(19) United States
(12) Patent Application Publication
(10) Pub. No.: US 2015/0276198 A1
(43) Pub. Date: Oct. 1, 2015

(54) LIGHT-EMITTING APPARATUS AND STRUCTURE FOR ATTACHING LIGHT-EMITTING APPARATUS TO HEAT SINK

(71) Applicant: SHARP KABUSHIKI KAISHA, Osaka-shi, Osaka (JP)

(72) Inventors: Toshio Hata, Osaka-shi (JP); Makoto Agatani, Osaka-shi (JP); Tomokazu Nada, Osaka-shi (JP); Yuhsuke Fujita, Osaka-shi (JP); Ippei Yamaguchi, Osaka-shi (JP); Masahiro Konishi, Osaka-shi (JP)

(73) Assignee: SHARP KABUSHIKI KAISHA, Osaka-shi, Osaka (JP)

(21) Appl. No.: 14/434,428

(22) PCT Filed: Oct. 10, 2013
(86) PCT No.: PCT/JP2013/077614

§ 371 Date: Apr. 9, 2015

(30) Foreign Application Priority Data
Oct. 19, 2012 (JP) 2012-232229
Jan. 16, 2013 (JP) 2013-005308
Feb. 6, 2013 (JP) 2013-021836

(51) Int. Cl. F21V 29/70; H01L 33/54; H01L 33/62; H01L 33/64; F21V 23/00; H01L 25/075

(52) U.S. Cl. CPC F21V 29/70; F21V 23/005; H01L 25/0753; H01L 33/62; H01L 33/644; H01L 33/54; F21Y 2101/02

(57) ABSTRACT

A light-emitting apparatus has a substrate (72) having a generally disc shape, a light-emitting part (76) having a plurality of LED chips (73) mounted on one main surface of the substrate (72), the plurality of LED chips (73) being sealed with a resin (74), and a heat-sink attachment part having a heat-sink attachment male thread (80) formed on a side surface of the substrate (72). When the attachment area of the substrate (72) to the heat sink is kept the same, the light-emitting part (76) may be enlarged, and when the light-emitting unit (76) is kept the same, the attachment area of the substrate (72) may be reduced.

### TECHNICAL FIELD

The present invention relates to COB (Chip on Board) type light-emitting apparatuses and structures for attaching a COB type light-emitting apparatus to a heat sink.

### BACKGROUND ART

Conventional methods for attaching a COB type light-emitting apparatus to a heat sink are known from JP 2012-4400 A (PTL1) disclosing a light-emitting device mounting substrate and also from JP 2010-251192 A (PTL2) disclosing an illuminating apparatus.

With regard to the light-emitting device mounting substrate, a plurality of divided copper sheet pieces are joined directly to one main surface of a rectangular plate-shaped zirconia-containing alumina substrate while an undivided copper sheet is joined directly to the other main surface. A plated coating is provided on surfaces of the divided copper sheet pieces and the surface of the undivided copper sheet. Then, mutually opposing side edges of the undivided copper sheet are provided with protruding portions protruding therefrom, and screw fitting portions each having a through hole or cutout for use of screwing involved in attachment to the heat sink are provided at the protruding portions.

With regard to the illuminating apparatus described above, on the other hand, an LED (Light Emitting Diode) module having LED chips mounted on a rectangular printed circuit board is screwed to a heat sink, with one edge side of the printed circuit board being pressed against the heat sink with a first angle member, and with another edge side of the board being pressed against the heat sink with a second angle member. In this way, the LED module is set into close contact with the heat sink.

However, in the conventional light-emitting device mounting substrate described above, the protruding portions for setting the rectangular zirconia-containing alumina substrate to the heat sink protrude from mutually opposing two side edges of the zirconia-containing alumina substrate. As a consequence, the zirconia-containing alumina substrate has an increased attachment area by a protruding extent of the protruding portions relative to its size proper, so that an illuminating part inclusive of the heat sink also has an increased size accordingly, which is a problem.

Also with the conventional illuminating apparatus, the rectangular LED module is screwed and fixed to the heat sink with the mutually opposing two side edges of the LED module being pressed against the heat sink with angle members. Each of the angle members has a shape like a rectangular plate material with opposite ends of the rectangular plate material being bent toward mutually opposite directions. And, one of the bent end portions of the angle members is screwed to the heat sink while the printed circuit board is pressed against the heat sink by the other bent end portion of the angle members.

Therefore, as in the case of the conventional light-emitting device mounting substrate, the illuminating apparatus has an increased attachment area to the heat sink by a protruding extent of the bent end portions screwed to the heat sink, so that an illuminating part of the apparatus inclusive of the heat sink also has an increased size accordingly, which is a problem.

Furthermore, since the printed circuit board is pressed against the heat sink by the other bent end portion of the angle member, a mounting area for the LED chips in the printed circuit board is decreased by an extent corresponding to the bent end portion, leading to a problem of a decreased light emission area.

Still more, in the above-described conventional light-emitting device mounting substrate and illuminating apparatus, since heads of screws are positioned at places of the protruding portions and the bent end portions, the protruding portions and the bent end portions need to be further increased in size by an amount corresponding to the heads of the screws.

### CITATION LIST

### Patent Literature

PTL1: JP 2012-4400 A
PTL2: JP 2010-251192 A

### SUMMARY OF INVENTION

### Technical Problem

A technical problem of the invention is, therefore, to provide a light emitting apparatus and a structure for attaching the light-emitting apparatus to a heat sink, the structure capable of decreasing the attachment area or increasing the light emission area.

### Solution to Problem

In order to solve the problem, a light-emitting apparatus according to an aspect of the present invention comprises:

a substrate having a generally disc shape;

a light-emitting part having a plurality of LED chips mounted on one main surface of the substrate, the plurality of LED chips being sealed with a resin; and

a heat-sink attachment part having a male thread for heat-sink attachment (referred to as “heat-sink attachment male thread” below) formed on a side surface of the substrate.

With this constitution, the light-emitting apparatus includes the heat-sink attachment part having the heat-sink attachment male thread (external thread) on the side surface of the substrate, the substrate being mounted with the plurality of LED chips. Therefore, the light-emitting apparatus may be attached to the heat sink by inserting the male thread of the heat-sink attachment part into the light-emitting apparatus attachment hole, provided in the heat sink, having a female thread (internal thread) formed on its inner surface. In this case, there is nothing that interferes with the light-emitting part of the light-emitting apparatus.

Thus, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

In one embodiment, the heat-sink attachment part is formed on a side surface that is located on the other main surface side of the substrate.

According to this embodiment, in the process of attaching the light-emitting apparatus to the heat sink, the one main surface side of the substrate protrudes from the heat sink. Therefore, what is required for the attaching of the light-emitting apparatus to the heat sink is to grasp and turn the protruding portion of the substrate. Thus, the light-emitting apparatus may be attached to the heat sink with high operability without causing any damage to the light-emitting part.

In one embodiment, the heat-sink attachment part is formed on a side surface of a smaller-diameter portion of the substrate, the smaller-diameter portion being located on the other main surface side of the substrate.

According to this embodiment, a step portion is formed between the one main surface side and the smaller-diameter portion in the substrate. Therefore, when the light-emitting apparatus is attached to the heat sink, the step portion is brought into close contact with the surface of the heat sink. Thus, heat releasability to the heat sink is improved.

In one embodiment, at least one flat surface is formed in a side surface of the larger-diameter portion of the substrate, the larger-diameter portion being located on the one main surface side of the substrate.

According to this embodiment, at least one flat surface is formed in the side surface of the larger-diameter portion of the substrate. The flat surface may make it allowable to use a wrench or spanner during the process of attaching the light-emitting apparatus to the heat sink, facilitating the tightening of the substrate against the heat sink. Thus, the light-emitting apparatus may be fixed to the heat sink with more reliability, so that the heat releasability may be enhanced.

In one embodiment, two flat surfaces are formed at mutually opposing positions in the side surface of the larger-diameter portion of the substrate.

According to this embodiment, the two mutually opposing flat surfaces are formed in the side surface of the larger-diameter portion of the substrate. During the process of attaching the light-emitting apparatus to the heat sink, using the mutually opposing two flat surfaces may make it possible to fix the light-emitting apparatus to the heat sink with more reliability, so that the heat releasability may be enhanced.

In one embodiment, a cross section of the larger-diameter portion in the substrate has a shape of polygon, and the flat surfaces form individual edges of the polygon.

According to this embodiment, the larger-diameter portion in the substrate is formed into a polygonal shape. Therefore, during the process of attaching the light-emitting apparatus to the heat sink, it may be implementable to use the wrench or spanner with ease, making it possible to fix the light-emitting apparatus to the heat sink with more reliability, so that the heat releasability may be enhanced.

In one embodiment, the light-emitting apparatus has a clamping member for holding the heat sink against the larger-diameter portion, the clamping member including a female thread to be engaged with the male thread of the heat-sink attachment part.

According to this embodiment, the light-emitting apparatus includes the clamping member to be engaged with the male thread of the heat-sink attachment part. Therefore, the heat sink may be held by the clamping member and the larger-diameter portion having at least one flat surface in the substrate, making it possible to fix the light-emitting apparatus to the heat sink with more reliability, so that the heat releasability may be enhanced.

In one embodiment, the light-emitting apparatus has two connector portions or land portions that are formed on the one main surface of the substrate at mutually opposing positions with a center line of the light-emitting part interposed therebetween,

the connector portions or land portions including a first connector portion or first land portion connected to one electrode of the LED chips and a second connector portion or second land portion connected to the other electrode of the LED chips, and

the first connector portion or first land portion and the second connector portion or second land portion being electrically connected to external lead wires.

According to this embodiment, for attachment of the light-emitting apparatus to a heat sink provided with two through holes corresponding to two lead wires for power feed to the one and other electrodes of the LED chips, preferably, the clamping operation with the clamping member may be performed after positioning the substrate such that the distances between the individual through holes of the heat sink and the individual connector portions or land portions become generally equal to each other and the shortest. In that case, distances between the individual through holes of the heat sink and the individual connector portions or land portions may be set generally equal to each other and moreover the shortest. Furthermore, electrical connections between the connector portions or land portions and the lead wires may be fulfilled without intercepting the light emission from the light-emitting part.

In one embodiment, the heat-sink attachment part is formed on a side surface of a larger-diameter portion of the substrate, the larger-diameter portion being located on the other main surface side of the substrate.

Heat of the light-emitting part released from the individual LED chips transfers toward peripheral portions of the substrate where temperatures are lower. According to this embodiment, the heat-sink attachment part is formed in the side surface of the larger-diameter portion formed on the other main surface side of the substrate. Therefore, in the case where the light-emitting apparatus is attached to the heat sink, heat of the light-emitting part is released toward the heat sink efficiently, displaying a smooth temperature gradient.

In one embodiment, the heat-sink attachment part is formed overall on the side surface of the substrate.

According to this embodiment, when the male thread of the heat-sink attachment part is screwed into the light-emitting apparatus attachment hole provided in the heat sink and having the female thread formed in its inner surface, the whole side surface and the bottom surface of the substrate of the light-emitting apparatus are set into close contact with the heat sink. Thus, heat of the light-emitting part is released to the heat sink efficiently via the whole side surface and the bottom surface of the substrate.

In one embodiment, the heat-sink attachment part includes at least any one of:

an undercut or clearance groove formed at an end portion on the one main surface side;

a chamfered portion formed at an end portion on the other main surface side; and

a smaller-diameter portion formed on the other main surface side between the undercut and the chamfered portion so as to adjoin the chamfered portion, the smaller-diameter portion being smaller in diameter than a portion on the one main surface side between the undercut and the chamfered portion and formed with a heat-sink attachment male thread,

the heat-sink attachment part further including a base portion formed of an area between the undercut and the smaller-diameter portion and provided with a heat-sink attachment male thread,

a top, or crest, of a thread ridge of the male thread formed in the smaller-diameter portion is smaller in diameter than a top of a thread ridge of the male thread formed in the base portion.

According to this embodiment, the heat-sink attachment part has at least any one of the undercut, the chamfered portion and the smaller-diameter portion. Therefore, if the heat-sink attachment part has the chamfered portion or the smaller-diameter portion, any inclination of the center axis of the male thread may easily be adjusted during the process of screwing the heat-sink attachment male thread with the female thread of the heat sink. Thus, the male thread may correctly be engaged with the female thread, so that thread bites of the male thread may be prevented.

Further, in another case where the heat-sink attachment part has the undercut, even if the male thread has been engaged with the female thread with the center axis of the male thread remaining quite slightly inclined relative to the center axis of the female thread, quite a slight deviation of the center axis of the male thread relative to the center axis of the female thread is corrected when the end portion of the female thread has reached the undercut, so that thread bites of the male thread may be prevented. As a result, close contactability with the surface of the heat sink may be improved.

Also, a light-emitting apparatus according to another aspect of the invention comprises:

a substrate;

a light-emitting part having a plurality of LED chips mounted on one main surface of the substrate, the plurality of LED chips being sealed with a resin;

a heat-sink attachment hole which is provided in proximity to the light-emitting part in the substrate and which is formed of a hole with a female thread formed in its inner surface; and

a heat-sink attachment screw to be engaged with the female thread of the heat-sink attachment hole, wherein

a head of the heat-sink attachment screw and the light-emitting part overlap with each other as viewed in an axial direction of the heat-sink attachment hole.

With this constitution, the head of the heat-sink attachment screw, which is to be engaged with the female thread of the heat-sink attachment hole provided in proximity to the light-emitting part in the substrate, and the light-emitting part overlap with each other as viewed in the axial direction of the heat-sink attachment hole. That is, the heat-sink attachment hole is provided in close proximity to the light-emitting part.

Thus, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

In one embodiment, the heat-sink attachment hole is provided in the substrate and in periphery of the light-emitting part.

According to this embodiment, it is possible to provide a plurality of above-described heat-sink attachment holes in periphery of the light-emitting part in the substrate. In this case, the substrate and the heat sink may be tightened together firmly by the plurality of heat-sink attachment holes and the plurality of heat-sink attachment screws.

In one embodiment, a space area with no LED chips mounted thereon is provided in a central portion of the light-emitting part, and the heat-sink attachment hole is provided in the space area.

A plurality of LED chips are mounted on the substrate. Therefore, under operation of the light-emitting apparatus, the central portion of the light-emitting part increases in temperature due to heat release from the LED chips.

According to this embodiment, the heat-sink attachment hole is provided in the central portion of the light-emitting part. Therefore, heat accumulated in the central portion of the light-emitting part may be released outside through the heat-sink attachment hole, so that temperature increases in the central portion of the light-emitting part may be suppressed. Thus, by the suppression of temperature increases in the central portion of the light-emitting part, the light-emitting apparatus may be operated with stability.

In one embodiment, the heat-sink attachment hole is a bottomed hole having an opening in the other main surface of the substrate.

According to this embodiment, the heat-sink attachment hole provided in the substrate is a bottomed hole. Therefore, an end portion of the heat-sink attachment screw is never exposed so that light absorption by the end portion of the heat-sink attachment screw may be prevented.

In one embodiment, the heat-sink attachment hole is a through hole having openings in the one main surface and the other main surface of the substrate.

According to this embodiment, during the process of tightening the substrate and the heat sink together with the heat-sink attachment screw, the heat-sink attachment screw is allowed to reach the top surface of the substrate, so that the substrate and the heat sink may be tightened together more firmly.

Also, a structure for attaching a light-emitting apparatus to a heat sink according to a further aspect of the invention comprises:

a light-emitting part having a plurality of LED chips mounted on a substrate;

a hole provided in the substrate and having a female thread formed in its inner surface;

a heat sink to which the substrate is attached; and

a through hole provided at a position in the heat sink corresponding to the hole of the substrate, the through hole communicating with the hole of the substrate and having a female thread formed in its inner surface, the female thread of the through hole adjoining the female thread of the substrate hole, wherein

the substrate and the heat sink are tightened together with a screw which is inserted through the through hole in the heat sink so as to be engaged with the female threads of the through hole and the hole of the substrate.

With this constitution, for tightening of the substrate and the heat sink with a screw, the screw is inserted through the through hole in the heat sink toward the hole of the substrate. Therefore, the head of the screw is allowed to extend beyond the substrate area as viewed in a plan view without the possibility of coming into contact with the light-emitting part. For this reason, the hole to be formed in the substrate may be formed in a peripheral portion of the substrate. In this case, the hole may be formed in close proximity to the light-emitting part.

That is, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

In one embodiment, the substrate has a shape of a rectangle, and the hole in the substrate is provided at each of two corner portions positioned on a diagonal line of the rectangle of the substrate.

According to this embodiment, by the two holes provided in the substrate and two through holes provided in the heat sink in correspondence to those holes, the substrate and the heat sink may be screwed or tightened together firmly.

In one embodiment, the hole of the substrate is provided in a central portion of the substrate.

A plurality of LED chips are mounted on the substrate. Therefore, under operation of the light-emitting apparatus, the central portion of the light-emitting part increases in temperature due to heat release from the LED chips.

According to this embodiment, the hole is provided in a central portion of the substrate. Therefore, heat accumulated in the central portion of the light-emitting part may be released outside through the hole, so that the temperature increase in the central portion of the light-emitting part may be suppressed. As a result of the suppression of the temperature increase in the central portion of the light-emitting part, the light-emitting apparatus may be operated with stability.

In this case, if a through hole is provided also in the central portion of the light-emitting part including the LED chips, it is possible to further enhance the heat releasability in the central portion of the light-emitting part.

In one embodiment, the hole provided in the substrate is a through hole.

According to this embodiment, during the process of tightening the substrate and the heat sink together with a screw, the screw is allowed to reach the top surface of the substrate, so that the substrate and the heat sink may be tightened together firmly.

In one embodiment, the hole provided in the substrate is a bottomed hole having an opening on the heat sink side.

According to this embodiment, the hole provided in the substrate is a bottomed hole. Therefore, an end portion of the screw is never exposed so that light absorption by the end portion of the screw may be prevented.

In one embodiment, the end portion of the screw exposed from the through hole provided in the substrate is covered with a white resin.

According to this embodiment, the end portion of the screw exposed from the through hole of the substrate is covered with the white resin. Therefore, light absorption by the end portion of the screw is reduced.

### Advantageous Effects of Invention

As is apparent from the above, the light-emitting apparatus according to an aspect of the present invention includes a heat-sink attachment part having a heat-sink attachment male thread on a side surface of the substrate, on which substrate a plurality of LED chips are mounted. Therefore, the light-emitting apparatus may be attached to the heat sink by engaging the male thread of the heat-sink attachment part with a female thread formed an inner surface of the light-emitting apparatus attachment hole provided in the heat sink. In this case, there is nothing that interferes with the light-emitting part of the light-emitting apparatus.

Thus, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

In the light-emitting apparatus according to another aspect of the present invention, a heat-sink attachment hole, which is formed of a hole with a female thread formed in its inner surface, is provided in proximity to the light-emitting part in the substrate. And, the head of a heat-sink attachment screw, which is to be engaged with the female thread of the heat-sink attachment hole, and the light-emitting part overlap with each other as viewed in the axial direction of the heat-sink attachment hole. That is, the heat-sink attachment hole is provided in close proximity to the light-emitting part.

Thus, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

In the structure for attaching a light-emitting apparatus to a heat sink according to a further aspect of the invention, for tightening of a substrate (which has a light-emitting part mounted with a plurality of LED chips) and a heat sink with a screw, the screw is inserted through the through hole in the heat sink toward the hole of the substrate. Therefore, the head of the screw is allowed to extend beyond the substrate area as viewed in a plan view without the possibility of coming into contact with the light-emitting part. For this reason, the hole to be formed in the substrate may be formed in a peripheral portion of the substrate. In this case, the hole may be formed in close proximity to the light-emitting part.

That is, the substrate does not require any protruding portions or angle members to be used for attachment to the heat sink. Therefore, if the attachment area of the substrate to the heat sink is made equal in size to the conventional substrate, the light-emitting part may be set larger in size than the conventional light-emitting part. On the other hand, if the light-emitting part is made equal in size to the conventional light-emitting part, the attachment area of the substrate may be set smaller in size than the conventional substrate. Thus, the attachment area may be decreased or the light emission area may be increased.

### BRIEF DESCRIPTION OF DRAWINGS

FIG. 1 is a view showing an attachment structure for attaching a light-emitting apparatus to a heat sink according to the present invention;

FIG. 2 is a view showing an attachment structure different from that of FIG. 1;

FIG. 3 is a view showing a modification of the attachment structure of FIG. 2;

FIG. 4 is a view showing an attachment structure different from those of FIGS. 1 to 3;

FIG. 5 is a view showing a light-emitting apparatus according to the invention;

FIG. 6 is a sectional view showing a state that the light-emitting apparatus shown in FIG. 5 is attached to a heat sink;

FIG. 7 is a sectional view showing modifications of the light-emitting apparatus shown in FIG. 5;

FIG. 8 is a view showing a light-emitting apparatus different from that of FIG. 5;

FIG. 9 is a sectional view showing a state that the light-emitting apparatus shown in FIG. 8 is attached to a heat sink;

FIG. 10 is a view showing a light-emitting apparatus different from those of FIGS. 5 and 8;

FIG. 11 is a view showing a modification of the light-emitting apparatus shown in FIG. 10;

FIG. 12 is a view showing a modification different from that of FIG. 11;

FIG. 13 is a view showing a modification different from those of FIGS. 11 and 12;

FIG. 14 is a view showing a modification different from those of FIGS. 11 to 13;

FIG. 15 is a view showing a modification different from those of FIGS. 11 to 14;

FIG. 16 is a view showing a state that the light-emitting apparatus shown in FIG. 15 is attached to a heat sink; and

FIG. 17 is a state that the light-emitting apparatus shown in FIG. 13 is attached to a heat sink.

### DESCRIPTION OF EMBODIMENTS

Hereinbelow, the present invention will be described in detail by way of embodiments thereof illustrated in the accompanying drawings.

### First Embodiment

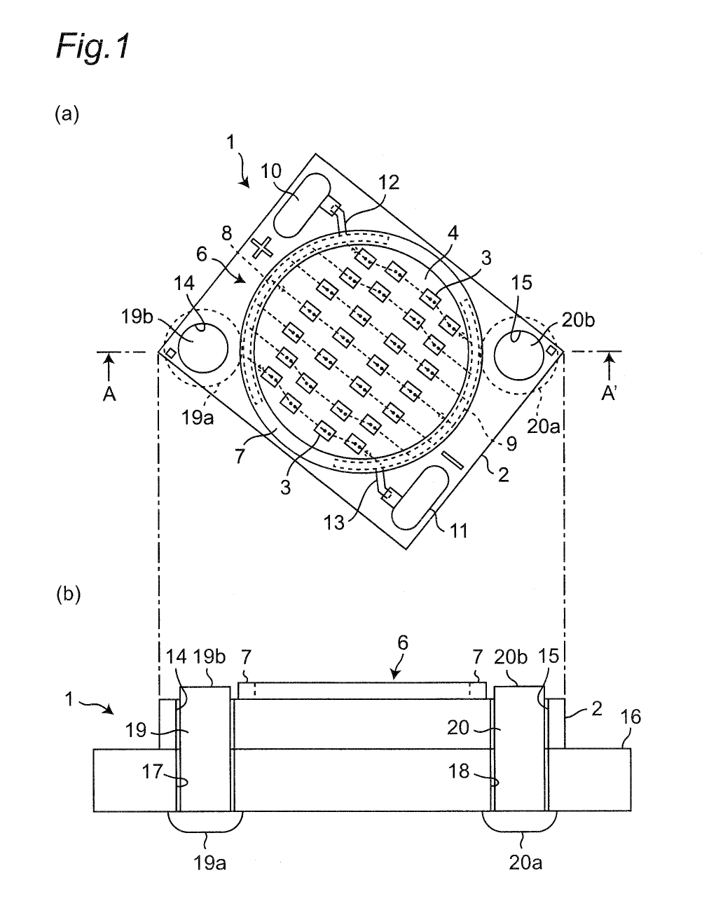

FIG. 1 is a view showing a structure for attaching a light-emitting apparatus to a heat sink according to this embodiment, wherein FIG. 1(a) is a top view and FIG. 1(b) is a sectional view taken along the line A-A′ of FIG. 1(a).

As shown in FIG. 1(a), a light-emitting apparatus 1 has a rectangular ceramic substrate 2 and a light-emitting part 6 formed on the rectangular ceramic substrate 2, the light-emitting part 6 having a plurality of LED chips 3 mounted on the substrate 2 and sealed with a transparent fluophor-containing resin 4.

Around the LED chips 3 on the ceramic substrate 2, circular arc-shaped anode-side wiring pattern 8 and cathode-side wiring pattern 9 are formed in opposition to each other so as to surround the plurality of LED chips 3. In this case, the anode-side wiring pattern 8 and the cathode-side wiring pattern 9 are placed so as to form part of an annular ring as viewed in a plan view.

An anode-electrode land portion 10 is formed at one of two corner portions positioned on a diagonal line of the rectangular ceramic substrate 2 while a cathode-electrode land portion 11 is formed at the other corner portion. Then, the anode-electrode land portion 10 is connected to the anode-side wiring pattern 8 by an anode-side conducting part 12. Also, the cathode-electrode land portion 11 is connected to the cathode-side wiring pattern 9 by a cathode-side conducting part 13.

The LED chips 3 are arranged in generally linear-shaped plural arrays so as to be generally parallel to one edge of the ceramic substrate 2. Then, out of the plural LED chips 3, LED chips arrayed roughly in one line are connected in series, and an LED chip 3 positioned at one end of each line is connected to the anode-side wiring pattern 8 with wire while an LED chip 3 positioned at the other end of each line is connected to the cathode-side wiring pattern 9 with wire.

In such a manner as to cover the anode-side wiring pattern 8 and the cathode-side wiring pattern 9 that are arranged so as to form part of an annular ring, an annular ring-shaped resin dam 7 for heat-sink attachment male thread heat-sink attachment male thread up the fluophor-containing resin 4 is formed. The resin dam 7, which is made from thermosetting resin as an example, is formed by pouring in the fluophor-containing resin 4 and thereafter performing heat treatment at curing temperatures.

Further, a through hole 14 is provided at one of two corner portions positioned on another diagonal line of the rectangular ceramic substrate 2, and a through hole 15 is provided at the other corner portion. Inner surfaces of both through holes 14, 15 have female threads.

Moreover, as shown in FIG. 1(b), in the heat sink 16, through holes 17, 18 are bored so as to communicate with the through holes 14, 15, respectively, of the ceramic substrate 2. In this case, inner surfaces of the through holes 17, 18 have female threads similar to those of the through holes 14, 15 and continuing therefrom.

The female threads and an engagement state between the female threads and the corresponding male threads are omitted from FIG. 1. Similar omissions are made in the subsequent figures.

The light-emitting apparatus 1 having the above-described structure is attached to the heat sink 16 in the following manner. That is, the light-emitting apparatus 1 is placed on the heat sink 16, and the through holes 14, 15 of the ceramic substrate 2 are aligned with the through holes 17, 18, respectively, of the heat sink 16. Then, a screw 19 engageable with the female threads of the through hole 14 and the through hole 17 is screwed through the through hole 17 of the heat sink 16 into the through hole 14 of the ceramic substrate 2. Similarly, a screw 20 engageable with the female threads of the through hole 15 and the through hole 18 is screwed through the through hole 18 of the heat sink 16 into the through hole 15 of the ceramic substrate 2. Thus, by tightening the screws 19, 20, the ceramic substrate 2 of the light-emitting apparatus 1 is set into close contact with the heat sink 16.

In this process, the screws 19, 20 are inserted along a direction from the through holes 17, 18 of the heat sink 16 toward the through holes 14, 15 of the ceramic substrate 2 in this embodiment. Therefore, heads 19a, 20a of the screws 19, 20 are positioned on the back surface side of the heat sink 16 opposite to its light-emitting apparatus 1 side so as to be in close contact with the back surface of the heat sink 16. For this reason, the heads 19a, 20a of the screws 19, 20 never contact the resin dam 7 and is allowed to extend beyond the ceramic substrate 2 as viewed in a plan view. Therefore, the through holes 14, 15 to be formed in the ceramic substrate 2 may be formed at the corner portions, which are included in peripheral portions of the rectangular ceramic substrate 2. In this case, the through holes 14, 15 may be formed in close proximity to the light-emitting part 6.

That is, the ceramic substrate 2 needs neither protruding portions nor angle members for the attachment to the heat sink 16.

Also, end portions 19b, 20b of the screws 19, 20 on the side opposite to the head 19a, 20a side are exposed from the through holes 14, 15 of the ceramic substrate 2. Therefore, for reduction of light absorption by the end portions 19b, 20b of the screws 19, 20, the end portions 19b, 20b of the screws 19, 20 exposed from the through holes 14, 15 are covered with a white resin (not shown).

That is, in this embodiment, the through holes 14, 15 of the ceramic substrate 2 serve as the heat-sink attachment holes. Also, the screws 19, 20 serve as the heat-sink attachment screws.

As described above, in the first embodiment, when the rectangular ceramic substrate 2 with the light-emitting part 6 formed thereon is attached to the heat sink 16, the screws 19, 20 are inserted from the heat sink 16 side. Therefore, the through holes 14, 15 to be formed in the ceramic substrate 2 may be formed at the corner portions of the rectangular ceramic substrate 2. In this case, the through holes 14, 15 may be formed in close proximity to the light-emitting part 6.

That is, according to this embodiment, if the attachment area of the ceramic substrate 2 to the heat sink 16 is made equal in size to the conventional substrate, the light-emitting part 6 may be set larger in size than the conventional light-emitting part. On the other hand, if the light-emitting part 6 is made equal in size to the conventional light-emitting part, the attachment area of the ceramic substrate 2 to the heat sink 16 may be set smaller in size than the conventional substrate. Thus, the attachment area may be decreased or the light emission area may be increased.

In addition, in this embodiment, female threads are formed both in the through holes 14, 15 on the light-emitting apparatus 1 side and in the through holes 17, 18 of the heat sink 16. However, even if the female threads of the through holes 17, 18 in the heat sink 16 are omitted, same effects as described above may be produced.

### Second Embodiment

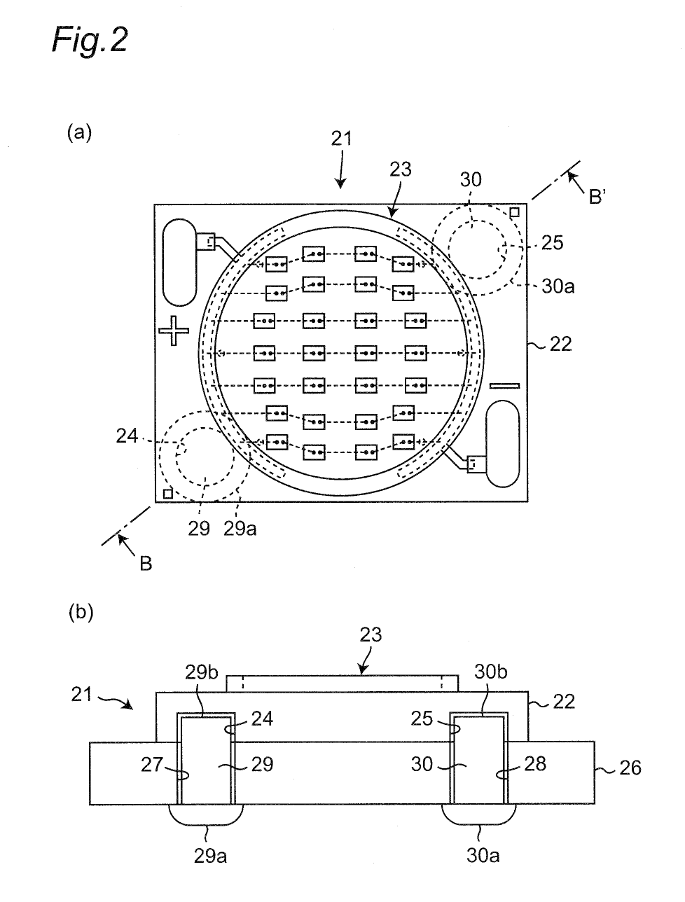

FIG. 2 is a view showing an attachment structure different of the light-emitting apparatus to the heat sink according to this embodiment, wherein FIG. 2(a) is a top view and FIG. 2(b) is a sectional view taken along the line B-B′ of FIG. 2(a).

As shown in FIG. 2(a), a light-emitting apparatus 21 is so constructed that a light-emitting part 23 identical in construction to the light-emitting part 6 of the first embodiment is formed on a rectangular ceramic substrate 22.

As shown in FIG. 2(a) and FIG. 2(b), the ceramic substrate 22 has a bottomed hole 24 having an opening on a heat sink 26 side thereof. The bottomed hole 24 is bored at one of two corner portions positioned on a diagonal line of the ceramic substrate 22 where no land portions for anode electrode and cathode electrode are formed. Also, another bottomed hole 25 having an opening on the heat sink 26 side is bored at the other corner portion of the ceramic substrate 22. Also, in the heat sink 26, through holes 27, 28 are bored so as to communicate with the holes 24, 25, respectively, of the ceramic substrate 22. In this case, the holes 24, 25 and the through holes 27, 28 are respectively formed with female threads (internal threads) which are continuous with each other.

The light-emitting apparatus 21 having the above-described structure is attached to the heat sink 26 in the following manner. That is, the light-emitting apparatus 21 is placed on the heat sink 26, and the holes 24, 25 in the ceramic substrate 22 are aligned with the through holes 27, 28, respectively, in the heat sink 26. Then, a screw 29 engageable with the female threads of the hole 24 and the through hole 27 is screwed through the through hole 27 in the heat sink 26 into the hole 24 in the ceramic substrate 22. Similarly, a screw 30 engageable with the female threads of the hole 25 and the through hole 28 is screwed through the through hole 28 in the heat sink 26 into the hole 25 in the ceramic substrate 22. Thus, by tightening the screws 29, 30, the ceramic substrate 22 of the light-emitting apparatus 21 is set into close contact with the heat sink 26.

In this process, the screws 29, 30 are inserted along a direction from the through holes 27, 28 of the heat sink 26 toward the holes 24, 25 of the light-emitting apparatus 21 in this embodiment. Therefore, heads 29a, 30a of the screws 29, 30 are positioned on the back surface side of the heat sink 26 opposite to its light-emitting apparatus 21 side so as to be in close contact with the back surface of the heat sink 26. Also, the holes 24, 25 are bottomed holes. For this reason, the screws 29, 30 never contact the light-emitting part 23 and is allowed to extend beyond the ceramic substrate 22 as viewed in a plan view. Therefore, the holes 24, 25 to be formed in the ceramic substrate 22 may be formed at the corner portions of the rectangular ceramic substrate 22. In this case, since the screws 29, 30 do not interfere with the light-emitting part 23 at all, the light-emitting part 23 may be formed so large as to overlap with the screws 29, 30 as viewed in a plan view.

That is, the ceramic substrate 22 needs neither protruding portions nor angle members for the attachment to the heat sink 26.

Also, the holes 24, 25 of the ceramic substrate 22 are bottomed holes. Therefore, end portions 29b, 30b of the screws 29, 30 are never exposed so that light absorption by the end portions 29b, 30b of the screws 29, 30 may be prevented.

That is, in this embodiment, the holes 24, 25 of the ceramic substrate 22 serve as the heat-sink attachment holes. Also, the screws 29, 30 serve as the heat-sink attachment screws.

As described above, in the second embodiment, when the rectangular ceramic substrate 22 with the light-emitting part 23 mounted thereon is attached to the heat sink 26, the screws 29, 30 are inserted from the heat sink 26 side. Therefore, the holes 24, 25 to be formed in the ceramic substrate 22 may be formed at the corner portions, which are peripheral portions of the rectangular ceramic substrate 22. In this case, the light-emitting part 23 may overlap with the heads 29a, 30a of the screws 29, 30 as viewed in a plan view.

That is, according to this embodiment, if the attachment area of the ceramic substrate 22 to the heat sink 26 is made equal in size to the conventional substrate, the light-emitting part 23 may be set larger in size than the conventional light-emitting part. On the other hand, if the light-emitting part 23 is made equal in size to the conventional light-emitting part, the attachment area of the ceramic substrate 22 may be set smaller in size than the conventional substrate. Thus, the attachment area may be decreased or the light emission area may be increased.

In addition, in this embodiment, both the holes 24, 25 of the light-emitting apparatus 21 and the through holes 27, 28 of the heat sink 26 are internally formed with female threads. However, even if the female threads of the through holes 27, 28 of the heat sink 26 are omitted, same effects as described above may be produced.

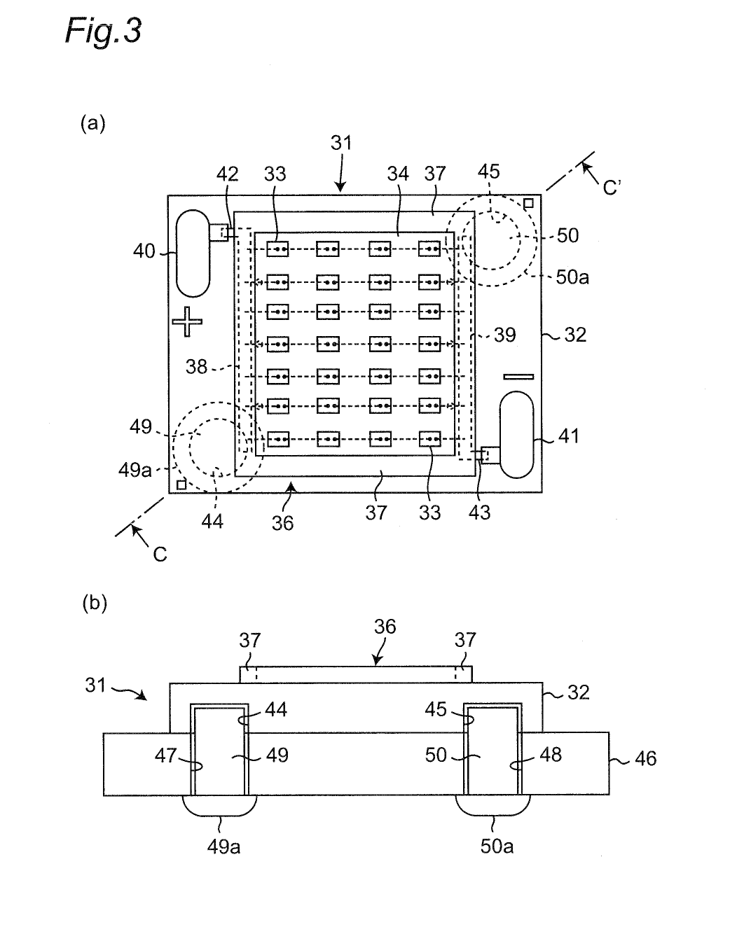

FIG. 3 is a view showing a modification of the attachment structure of the light-emitting apparatus to the heat sink according to the second embodiment, in which FIG. 3(a) is a top view and FIG. 3(b) is a sectional view taken along the line C-C′ of FIG. 3(a).

As shown in FIG. 3(a), a light-emitting apparatus 31 has a rectangular ceramic substrate 32 and a light-emitting part 36 formed on a rectangular ceramic substrate 32, the light-emitting part 36 having a plurality of LED chips 33 mounted on the ceramic substrate 32 and sealed with a transparent fluophor-containing resin 34.

Around the LED chips 33 on the ceramic substrate 32, linear-shaped anode-side wiring pattern 38 and cathode-side wiring pattern 39 are formed in opposition to each other so as to sandwich the plurality of LED chips 33. Further, an anode-electrode land portion 40 is formed at one of two corner portions positioned on a diagonal line of the rectangular ceramic substrate 32, while a cathode-electrode land portion 41 is formed at the other corner portion. Then, the anode-electrode land portion 40 is connected to the anode-side wiring pattern 38 by an anode-side conducting part 42. Also, the cathode-electrode land portion 41 is connected to the cathode-side wiring pattern 39 by a cathode-side conducting part 43.

The LED chips 33 are arranged in linear-shaped plural arrays so as to be generally parallel to one edge of the ceramic substrate 32. Then, out of the plural LED chips 33, LED chips arrayed roughly in one line are interconnected in series, and an LED chip 33 positioned at one end of each line is connected to the anode-side wiring pattern 38 with wire while an LED chip 33 positioned at the other end of each line is connected to the cathode-side wiring pattern 39 with wire.

In such a manner as to cover the linear-shaped anode-side wiring pattern 38 and cathode-side wiring pattern 39 that are arranged so as to be opposed to each other, a quadrangular-shaped resin dam 37 for damming up the fluophor-containing resin 34 is formed. The resin dam 37, which is made from thermosetting resin as an example, is formed by pouring in the fluophor-containing resin 34 and thereafter performing heat treatment at curing temperatures.

As shown in FIG. 3(a) and FIG. 3(b), the ceramic substrate 32 has a bottomed hole 44 having an opening on the heat sink 46 side thereof. The bottomed hole 44 is bored at one of two corner portions positioned on a diagonal line of the ceramic substrate 32 where no land portions for the anode electrode and the cathode electrode are formed, and another bottomed hole 45 having an opening on the heat sink 46 side is bored at the other corner portion of the ceramic substrate 32. Further, in the heat sink 46, through holes 47, 48 are bored so as to communicate with the holes 44, 45, respectively, of the ceramic substrate 32. In this case, the holes 44, 45 and the through holes 47, 48 are respectively formed with female threads which are continuous with each other.

When the light-emitting apparatus 31 having the above-described structure is attached to the heat sink 46, a screw 49 engageable with the female threads of the hole 44 and the through hole 47 is screwed through the through hole 47 of the heat sink 46 into the hole 44 of the ceramic substrate 32. Similarly, a screw 50 engageable with the female threads of the hole 45 and the through hole 48 is screwed through the through hole 48 of the heat sink 46 into the hole 45 of the ceramic substrate 32.

That is, this modification is identical to the structure for attaching the light-emitting apparatus 21 to the heat sink 26 shown in FIG. 2 except that the light-emitting part 36 as a whole is formed into a quadrangular shape.

Accordingly, also in this modification, end portions of the screws 49, 50 are never exposed so that light absorption by the end portions of the screws 49, 50 may be prevented. Moreover, the holes 44, 45 to be formed in the ceramic substrate 32 may be formed at the corner portions of the rectangular ceramic substrate 32. In this case, the light-emitting part 36 is allowed to overlap with the heads 49a, 50a of the screws 49, 50 as viewed in a plan view.

That is, if the attachment area of the ceramic substrate 32 to the heat sink 46 is made equal in size to the conventional substrate, the light-emitting part 36 may be set larger in size than the conventional light-emitting part. On the other hand, if the light-emitting part 36 is made equal in size to the conventional light-emitting part, the attachment area of the ceramic substrate 32 may be set smaller in size than the conventional substrate. Thus, the attachment area may be decreased or the light emission area may be increased.

### Third Embodiment

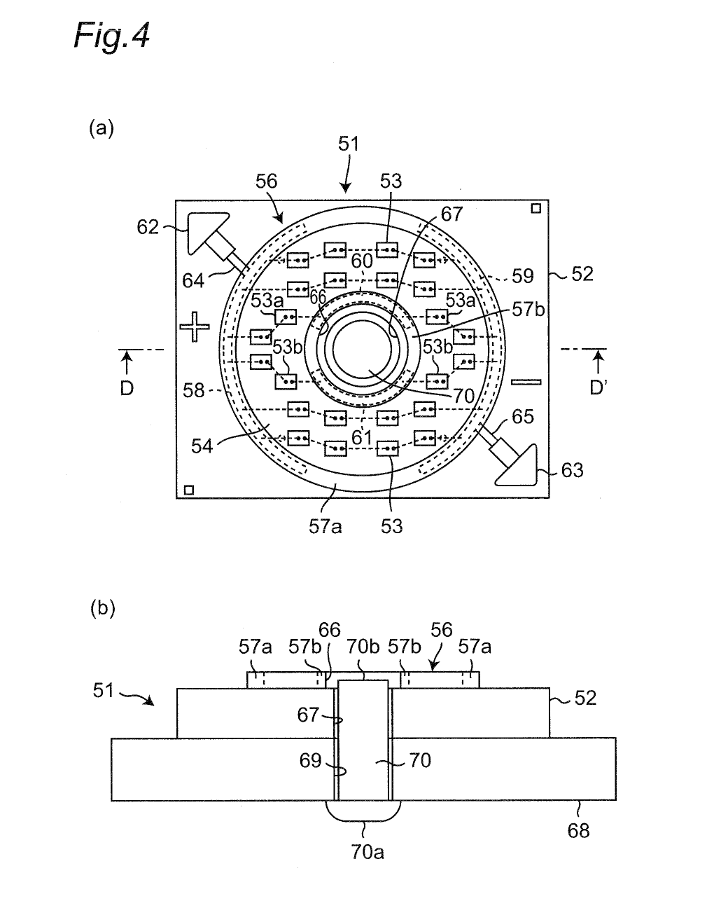

FIG. 4 is a view showing an attachment structure of a light-emitting apparatus to a heat sink according to this embodiment, in which FIG. 4(a) is a top view and FIG. 4(b) is a sectional view taken along the line D-D′ of FIG. 4(a).

As shown in FIG. 4(a), a light-emitting apparatus 51 has a rectangular ceramic substrate 52 and a light-emitting part 56 formed on the rectangular ceramic substrate 52, the light-emitting part 56 having a plurality of LED chips 53 mounted on the ceramic substrate 52 and sealed with a transparent fluophor-containing resin 54.

Around the LED chips 53 on the ceramic substrate 52, a circular arc-shaped anode-side wiring pattern 58 and a circular arc-shaped cathode-side wiring pattern 59 are formed in opposition to each other so as to surround the plurality of LED chips 53. In this case, the anode-side wiring pattern 58 and the cathode-side wiring pattern 59 are placed so as to form part of an annular ring as viewed in a plan view. Further, in central portion within the annular ring, circular arc-shaped wiring pattern 60 and wiring pattern 61 are formed in opposition to each other in a direction orthogonal to the direction in which the anode-side wiring pattern 58 and the cathode-side wiring pattern 59 are opposed. The wiring patterns 60 and 61 are placed so as to form part of an annular ring as viewed in a plan view.

In such a manner so as to cover the anode-side wiring pattern 58 and the cathode-side wiring pattern 59 that are arranged so as to form part of an annular ring, an annular ring-shaped resin dam 57a for damming up the fluophor-containing resin 54 is formed. Also, in such a manner so as to cover the wiring pattern 60 and the wiring pattern 61 that are arranged so as to form part of an annular ring, an annular ring-shaped resin dam 57b for damming up the fluophor-containing resin 54 is formed. The resin dams 57a, 57b, which are made from thermosetting resin as an example, are formed by pouring in the fluophor-containing resin 54 and thereafter performing heat treatment at curing temperatures.

The plurality of LED chips 53 placed between the resin dams 57a, 57b are arranged in generally linear-shaped plural arrays so as to be generally parallel to one edge of the ceramic substrate 52. However, the linearity of the arrangement is disordered in vicinities of the resin dam 57b. Then, out of the plural LED chips 53, LED chips arrayed roughly in one line are interconnected in series, and an LED chip 53 positioned at one end of each line is connected to the anode-side wiring pattern 58 with wire while an LED chip 53 positioned at the other end of each line is connected to the cathode-side wiring pattern 59 with wire.

Further, in a location where a wiring line for series connection of LED chips 53 arrayed roughly in one line would intersect the wiring pattern 60, two LED chips 53a and 53a that would be positioned at both ends of the wiring line are connected to each other via the wiring pattern 60. Similarly, two LED chips 53b positioned at both ends of a wiring line that would intersect the wiring pattern 61 are connected to each other via the wiring pattern 61.

In this way, the circular-shaped light-emitting part 56 is formed up, where a through hole 66 with no fluophor-containing resin 54 filled therein is provided at a central portion of the light-emitting part 56.

An anode-electrode land portion 62 is formed at one of two corner portions positioned on a diagonal line of the rectangular ceramic substrate 52, while a cathode-electrode land portion 63 is formed at the other corner portion. Then, the anode-electrode land portion 62 is connected to the anode-side wiring pattern 58 by an anode-side conducting part 64. Also, the cathode-electrode land portion 63 is connected to the cathode-side wiring pattern 59 by a cathode-side conducting part 65.

Further, a through hole 67 smaller in diameter than the through hole 66 of the light-emitting part 56 is bored at a center of the rectangular ceramic substrate 52. A female thread is formed in an inner surface of the through hole 67.

Furthermore, as shown in FIG. 4(b), a through hole 69 communicating with the through hole 67 of the ceramic substrate 52 is bored at a center of a heat sink 68. In this case, a female thread continuing to the female thread of the through hole 67 is formed on the inner surface of the through hole 69.

The light-emitting apparatus 51 having the above-described structure is attached to the heat sink 68 in the following manner. That is, the light-emitting apparatus 51 is placed on the heat sink 68, and the through hole 67 in the ceramic substrate 52 is aligned with the through hole 69 in the heat sink 68. Then, a screw 70 engageable with the female threads of the through hole 67 and the through hole 69 is screwed through the through hole 69 of the heat sink 68 into the through hole 67 of the ceramic substrate 52. Thus, by tightening the screw 70, the ceramic substrate 52 of the light-emitting apparatus 51 is set into close contact with the heat sink 68.

In this process, a head 70a of the screw 70 is positioned on the back surface side of the heat sink 68 opposite to its light-emitting apparatus 51 side in this embodiment. For this reason, the head 70a of the screw 70 never interferes with the light-emitting part 56 and is allowed to overlap with the ceramic substrate 52 area as viewed in a plan view.

That is, the ceramic substrate 52 needs neither protruding portions nor angle members for the attachment to the heat sink 68.

Also, an end portion 70b of the screw 70 on the side opposite to the head 70a side is exposed from the through hole 67 of the ceramic substrate 52. Therefore, for reduction of light absorption by the end portion 70b of the screw 70, the position of the end portion 70b is set lower than the top surface of the light-emitting part 56. Moreover, the end portion 70b of the screw 70 exposed from the through hole 67 is covered with a white resin (not shown).

That is, in this embodiment, the through hole 67 of the ceramic substrate 52 serves as the heat-sink attachment hole. Also, the screw 70 serves as the heat-sink attachment screw.

As described above, in the third embodiment, when the rectangular ceramic substrate 52 with the light-emitting part 56 formed thereon is attached to the heat sink 68, the screw 70 is inserted from the heat sink 68 side. Therefore, the head 70a of the screw 70 is allowed to overlap with the light-emitting part 56 as viewed in a plan view.

That is, according to this embodiment, if the attachment area of the ceramic substrate 52 to the heat sink 68 is made equal in size to the conventional substrate, the light-emitting part 56 may be set larger in size than the conventional light-emitting part. On the other hand, if the light-emitting part 56 is made equal in size to the conventional light-emitting part, the attachment area of the ceramic substrate 52 may be set smaller in size than the conventional substrate. Thus, the attachment area may be decreased or the light emission area may be increased.

In addition, the light-emitting part 56 on the ceramic substrate 52 includes the plurality of LED chips 53. Therefore, while the light-emitting apparatus 51 is in operation, a central portion of the light-emitting part 56 increases in temperature due to hear release from the individual LED chips 53. In this embodiment, the through hole 66 is formed in the center of the light-emitting part 56, and the through hole 67 communicating with the through hole 66 is formed in the center of the ceramic substrate 52. Thus, heat accumulated in the central portion of the light-emitting part 56 may be released outside through the through hole 66, so that temperature increases in the central portion of the light-emitting part 56 may be suppressed.

That is, according to this embodiment, temperature increases in the central portion of the light-emitting part 56 are suppressed, whereby the light-emitting apparatus 51 may be operated with stability.

Further, in this embodiment, the through hole 67 is formed in central portion of the ceramic substrate 52 so that the end portion 70b of the screw 70 is exposed from the through hole 67 of the ceramic substrate 52. However, it is also allowable that, as in the second embodiment, a bottomed hole communicating with the through hole 69 of the heat sink 68 is provided in the central portion of the ceramic substrate 52 and that the bottomed hole is formed with a female thread continuing from the female thread of the through hole 69. In this case, the through hole 66 in the light-emitting part 56 is eliminated and since the screw 70 never interferes with the light-emitting part 56, LED chips 53 may be mounted also in the central portion of an aluminum substrate 55.

In that case, the hole of the ceramic substrate 52 is a bottomed hole. Accordingly, the end portion 70b of the screw 70 is never exposed, so that light absorption by the end portion 70b of the screw 70 may be prevented.

In the above-described individual embodiments, the substrates 2, 22, 32, 52 on which the LED chips 3, 33, 53, 53a, 53b are mounted are provided by ceramic substrates. However, the substrates are not limited to the ceramic substrates. The substrate may be, for example, a metal core substrate in which an insulating layer is formed on a surface of a metal substrate. In short, the substrate needs only to be an insulated substrate.

Also in the above individual embodiments, the sealing resins 4, 34, 54 for sealing the LED chips 3, 33, 53, 53a, 53b are fluophor-containing resins. However, the sealing resin does not necessarily need to contain fluophor.

### Fourth Embodiment

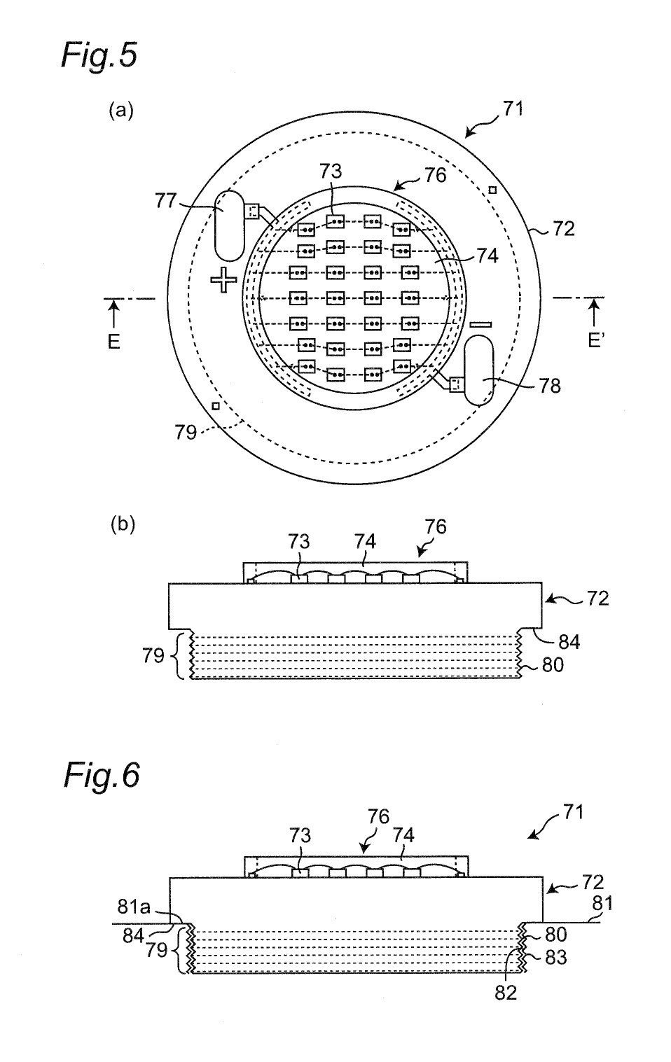

FIG. 5 is a view showing a light-emitting apparatus according to this embodiment, in which FIG. 5(a) is a top view and FIG. 5(b) is a sectional view taken along the line E-E′ of FIG. 5(a). FIG. 6 is a sectional view which shows a state that the light-emitting apparatus shown in FIG. 5 is attached to a heat sink, and which corresponds to FIG. 5(b).

As shown in FIG. 5(a), a light-emitting apparatus 71 has a generally circular-shaped ceramic substrate 72 and a light-emitting part 76 formed on the ceramic substrate 72, the light-emitting part 76 having a plurality of LED chips 73 mounted on the ceramic substrate 72 and sealed with a fluophor-containing resin 74. In this case, the light-emitting part 76, an anode-electrode land portion 77 and a cathode-electrode land portion 78 are provided in the same construction as the light-emitting part 6, the anode-electrode land portion 10 and the cathode-electrode land portion 11 shown in FIG. 1.

In this embodiment, as shown in FIG. 5(b), the ceramic substrate 72 has a smaller-diameter portion 79 on its back surface (the claimed other main surface) side opposite from its top surface (the claimed one main surface) that is a surface for formation of the light-emitting part 76. The smaller-diameter portion 79 has a diameter smaller than that of the top surface side. A male thread 80 is formed on the side surface of the smaller-diameter portion 79 to form the heat-sink attachment part.

Further, as shown in FIG. 6, a bottomed hole 82, into which the smaller-diameter portion 79 of the ceramic substrate 72 is to be inserted, is bored in a heat sink 81. A female thread 83 to be engaged with the male thread 80 of the ceramic substrate 72 is formed in the side surface of the hole 82.

With regard to the light-emitting apparatus 71 having the above-described structure, the male thread 80 formed in the smaller-diameter portion 79 of the ceramic substrate 72 is engaged with the female thread 83 of the heat sink 81. Thus, by tightening the ceramic substrate 72 against the heat sink 81, a step portion 84 (see FIG. 5(b)) at the boundary between a larger-diameter portion and the smaller-diameter portion 79 in the ceramic substrate 72 is set into close contact with a surface 81a of the heat sink 81.

In this case, as concerns release of the heat from the ceramic substrate 72 by contact between the step portion 84 of the ceramic substrate 72 and the surface 81a of the heat sink 81, it may be enough to form the male thread 80 merely in the smaller-diameter portion 79 of the ceramic substrate 72. However, in view of the heat of the light-emitting part 76 transferring toward peripheral portions of the ceramic substrate 72 where temperatures are lower, it is preferable that the diameter of the smaller-diameter portion 79 of the ceramic substrate 72 is larger than the diameter of the light-emitting part 6.

As described above, in this fourth embodiment, the light-emitting apparatus 71 is so constructed that the smaller-diameter portion 79 is provided on the back surface side of the generally circular-shaped ceramic substrate 72, with the generally circular-shaped light-emitting part 76 being formed on the top surface of the substrate 72, and that the smaller-diameter portion 79 is formed with the male thread 80. Therefore, when the male thread 80 on the back surface side of the light-emitting apparatus 71 is engaged with the female thread 83 of the heat sink 81 to attach the light-emitting apparatus 71 to the heat sink 81, there is nothing that interferes with the light-emitting part 76 of the light-emitting apparatus 71.

Accordingly, also in this embodiment, if the attachment area of the ceramic substrate 72 to the heat sink 81 is made equal in size to the conventional substrate, the light-emitting part 76 may be set larger in size than the conventional light-emitting part. On the other hand, if the light-emitting part 76 is made equal in size to the conventional light-emitting part, the attachment area of the ceramic substrate 72 may be set smaller in size than the conventional substrate. Thus, the attachment area may be decreased or the light emission area may be increased.

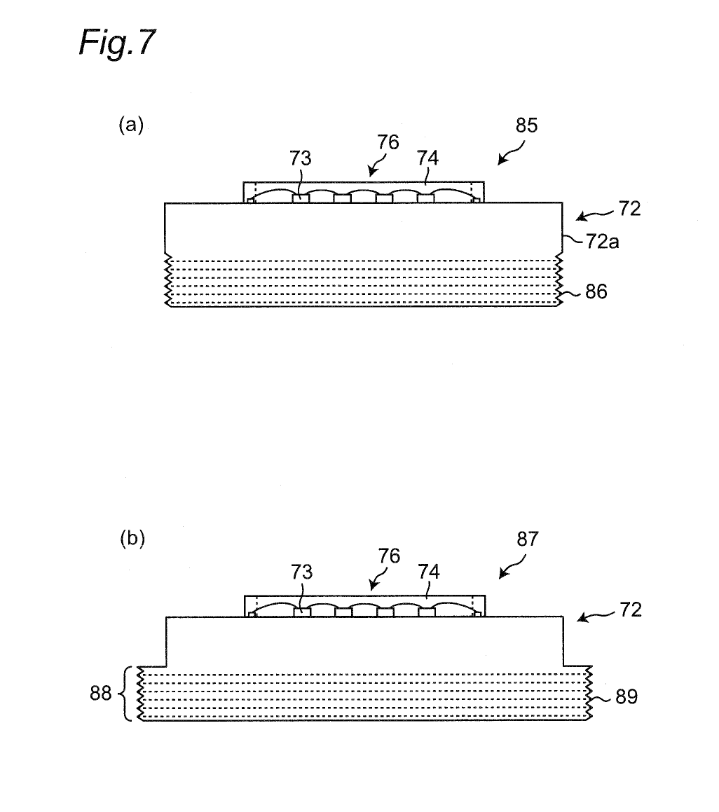

FIG. 7 is a view showing modifications of the light-emitting apparatus according to the fourth embodiment. In these modifications, the same component members as in the light-emitting apparatus 71 shown in FIG. 5 are designated by the same reference signs and description on those component members will be omitted.

In a light-emitting apparatus 85 shown in FIG. 7 (a), no smaller-diameter portion is formed on the back surface side of the generally circular-shaped ceramic substrate 72 opposite to its top surface that is the surface for formation of the light-emitting part 76. That is, a male thread 86 is formed directly on the back surface side of a side surface 72a of the ceramic substrate 72 to form the heat-sink attachment part. Therefore, in this case, it is necessary that a bottomed hole into which the ceramic substrate 72 is to be inserted is bored in the heat sink and a female thread to be engaged with the male thread 86 on the ceramic substrate 72 side is formed in the side surface of the hole. In this case, the smaller-diameter portion does not need to be formed, and it is necessary to merely form the male thread 86 in the side surface 72a of the ceramic substrate 72. Thus, the formation of the heat-sink attachment part is facilitated.

In a light-emitting apparatus 87 shown in FIG. 7(b), on the back surface side of the generally circular-shaped ceramic substrate 72 opposite to its top surface that is the surface for formation of the light-emitting part 76, a larger-diameter portion 88 having a diameter larger than the top surface side diameter is formed. A male thread 89 is formed on the surface of the larger-diameter portion 88 to form the heat-sink attachment part. Therefore, in this case, it is necessary that a bottomed hole into which the larger-diameter portion 88 of the ceramic substrate 72 is to be inserted is bored in the heat sink and a female thread to be engaged with the male thread 89 on the ceramic substrate 72 side is formed on the side surface of the hole.

Heat of the light-emitting part 76 due to heat release from the individual LED chips 73 transfers toward peripheral portions of the ceramic substrate 72 where temperatures are lower. According to this modification, the male thread 89 is formed on the side surface of the larger-diameter portion 88 of the ceramic substrate 72. Therefore, in the case where the light-emitting apparatus 87 is attached to a heat sink, heat of the light-emitting part 76 is released toward the heat sink efficiently forming a smooth temperature gradient.

### Fifth Embodiment

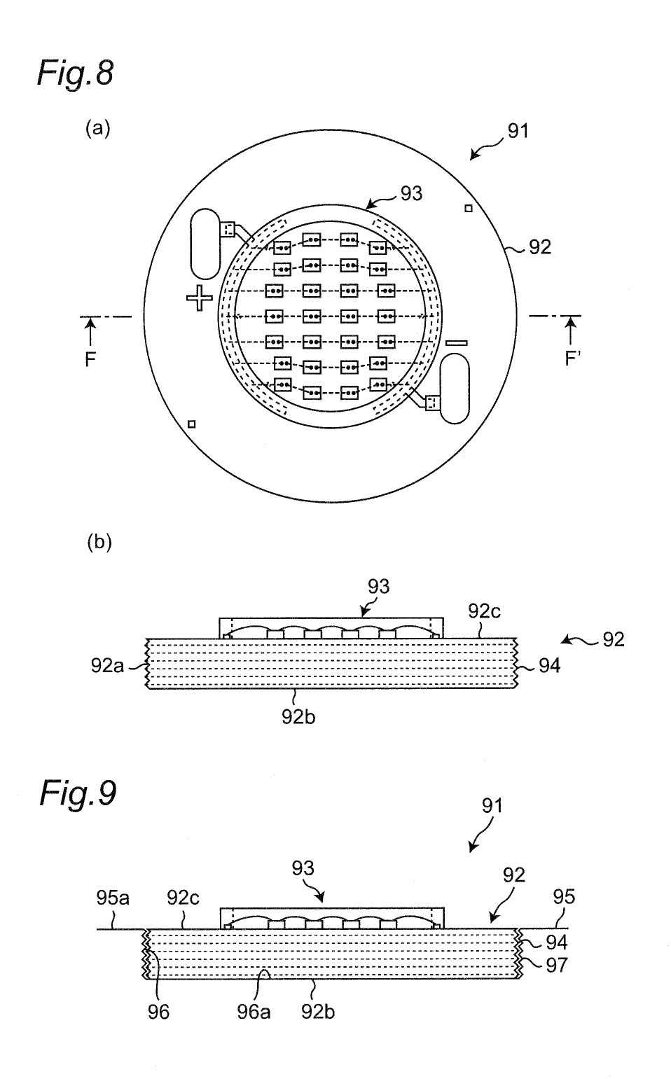

FIG. 8 is a view showing a light-emitting apparatus according to this embodiment, wherein FIG. 8(a) is a top view and FIG. 8(b) is a sectional view taken along the line F-F′ of FIG. 8(a). FIG. 9 is a sectional view which shows a state that the light-emitting apparatus shown in FIG. 8 is attached to a heat sink, and which corresponds to FIG. 8(b).

As shown in FIG. 8(a), a light-emitting apparatus 91 is so constructed that a light-emitting part 93 having the same construction as the light-emitting part 76 of the fourth embodiment is provided on a generally circular-shaped ceramic substrate 92. In this embodiment, as shown in FIG. 8(b), a male thread 94 is formed over the entire side surface 92a of the ceramic substrate 92 to form the heat-sink attachment part.

Further, as shown in FIG. 9, a bottomed hole 96 into which the ceramic substrate 92 is to be inserted is bored in a heat sink 95. A female thread 97 to be engaged with the male thread 94 of the ceramic substrate 92 is formed on the side surface of the hole 96. In this case, the hole 96 of the heat sink 95 has a depth equal to the thickness of the ceramic substrate 92. Therefore, when the male thread 94 formed on the side surface 92a of the ceramic substrate 92 is engaged with the female thread 97 of the heat sink 95 so that the ceramic substrate 92 is tightened against the heat sink 95, a bottom surface 92b of the ceramic substrate 92 may be set into close contact with a bottom surface 96a of the hole 96 of the heat sink 95. In this state, a top surface 92c of the ceramic substrate 92 is generally flush with a top surface 95a of the heat sink 95.

Accordingly, when the male thread 94 of the ceramic substrate 92 is engaged with the female thread 97 of the light-emitting apparatus attachment hole 96 provided in the heat sink 95, the whole side surface 92a and the bottom surface 92b of the ceramic substrate 92 in the light-emitting apparatus 91 are set into close contact with the heat sink 95. Thus, heat of the light-emitting part 93 is released to the heat sink efficiently via the whole side surface 92a and the bottom surface 92b of the ceramic substrate 92.

As described above, in the light-emitting apparatus 91 of the fifth embodiment, the male thread 94 is formed on the side surface 92a of the generally circular-shaped ceramic substrate 92 on the top surface of which the generally circular-shaped light-emitting part 93 is provided. Thus, there is nothing that interferes with the light-emitting part 93 of the light-emitting apparatus 91 during the process in which the male thread 94 of the light-emitting apparatus 91 is engaged with the female thread 97 of the heat sink 95 to fulfill the attachment of the light-emitting apparatus 91 to the heat sink 95.

Accordingly, in this embodiment as well, if the attachment area of the ceramic substrate 92 to the heat sink 95 is made equal in size to the conventional substrate, the light-emitting part 93 may be set larger in size than the conventional light-emitting part. On the other hand, if the light-emitting part 93 is made equal in size to the conventional light-emitting part, the attachment area of the ceramic substrate 92 may be set smaller in size than the conventional substrate. Thus, the attachment area may be decreased or the light emission area may be increased.

### Sixth Embodiment

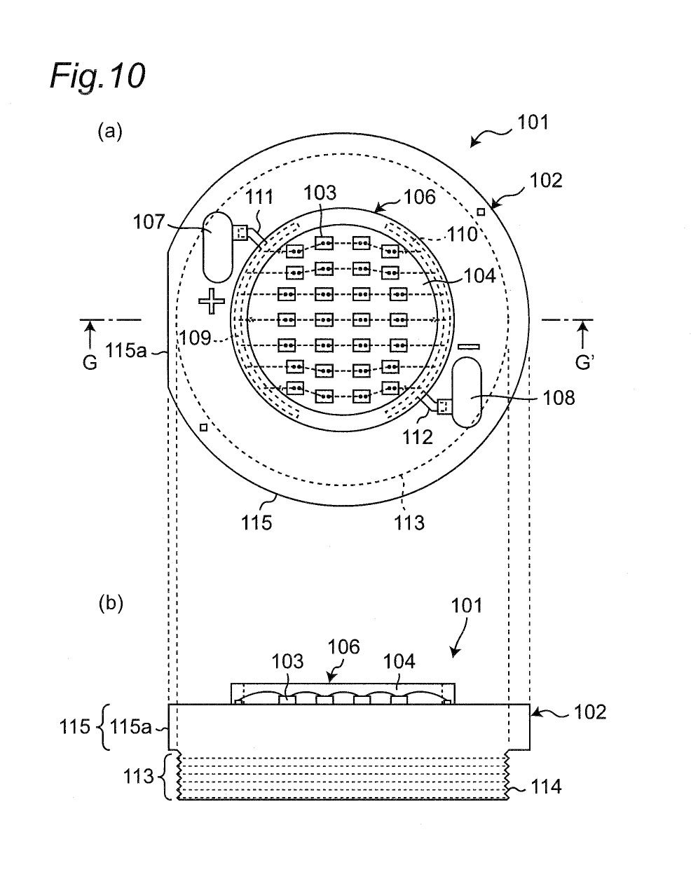

FIG. 10 is a view showing a light-emitting apparatus according to this embodiment, wherein FIG. 10(a) is a top view and FIG. 10(b) is a sectional view taken along the line G-G′ of FIG. 10(a). This embodiment relates to a light-emitting apparatus having at least one flat surface in the side surface of a head portion of the light-emitting apparatus.

As shown in FIG. 10(a), the light-emitting apparatus 101 has a generally circular-shaped Cu (copper) substrate 102 and a light-emitting part 106 provided thereon, the light-emitting part 106 having a plurality of LED chips 103 mounted on the Cu substrate 102 and sealed with a fluophor-containing resin 104. The light-emitting part 106, an anode-electrode land portion 107 and a cathode-electrode land portion 108 are identical in structure to the light-emitting part 6, the anode-electrode land portion 10 and the cathode-electrode land portion 11, respectively, shown in FIG. 1.

However, in this embodiment, there is provided an insulating layer (not shown) made from zirconia-based ceramic material in areas between the Cu substrate 102 and such members as an anode wiring pattern 109, a cathode wiring pattern 110, the anode-electrode land portion 107, the cathode-electrode land portion 108, an anode-side conducting part 111 and a cathode-side conducting part 112. Alternatively, an insulating layer made from zirconia-based ceramic material may be formed on the entire top surface of the Cu substrate 102 and, the anode wiring pattern 109, the cathode wiring pattern 110, the anode-electrode land portion 107, the cathode-electrode land portion 108, the anode-side conducting part 111, the cathode-side conducting part 112 and the LED chips 103 may be mounted on the insulating layer.

In this embodiment, the Cu substrate 102 has a smaller-diameter portion 113 on its back surface (the claimed other main surface) side opposite from its top surface (the claimed one main surface) that is a surface for formation of the light-emitting part 106. The smaller-diameter portion 113 has a diameter smaller than that of the top surface side. A male thread 114 is formed on the side surface of the smaller-diameter portion 113 to form the heat-sink attachment part. Also, one flat surface 115a is formed in the side surface of a larger-diameter portion 115 of the Cu substrate 102.

With regard to the light-emitting apparatus 101 having the above-described structure, the male thread 114 formed in the smaller-diameter portion 113 of the generally circular-shaped Cu substrate 102 is engaged with the female thread of the light-emitting apparatus attachment hole in the heat sink (not shown). Thus, by tightening the Cu substrate 102 against the heat sink, the Cu substrate 102 is set into close contact with the surface of the heat sink.

In this case, one flat surface 115a is provided in the larger-diameter portion 115 of the generally circular-shaped Cu substrate 102 in the light-emitting apparatus 101. Therefore, during the process of attaching the light-emitting apparatus 101 to the heat sink, using this flat surface 115a may make it easier to tighten the Cu substrate 102, facilitating the fixing of the light-emitting apparatus 101 to the heat sink. In addition, a distance between the flat surface 115a and the side surface of the larger-diameter portion 115 facing the flat surface 115a is preferably set to a standard size. In this case, it is allowable to use a wrench or spanner for tightening of the Cu substrate 102.

In this embodiment as well, if the attachment area of the Cu substrate 102 to the heat sink is made equal in size to the conventional substrate, the light-emitting part 106 may be set larger in size than the conventional light-emitting part. On the other hand, if the light-emitting part 106 is made equal in size to the conventional light-emitting part, the attachment area of the Cu substrate 102 may be set smaller in size than the conventional substrate. Thus, the attachment area may be decreased or the light emission area may be increased.

In this embodiment, the light-emitting apparatus 101 having one flat surface 115a in the larger-diameter portion 115 of the Cu substrate 102 is taken as an example. However, the invention is not limited to an embodiment having only one flat surface, and the light-emitting apparatus may have a plurality of flat surfaces or polygonal shapes as shown in the following modifications with no problem.

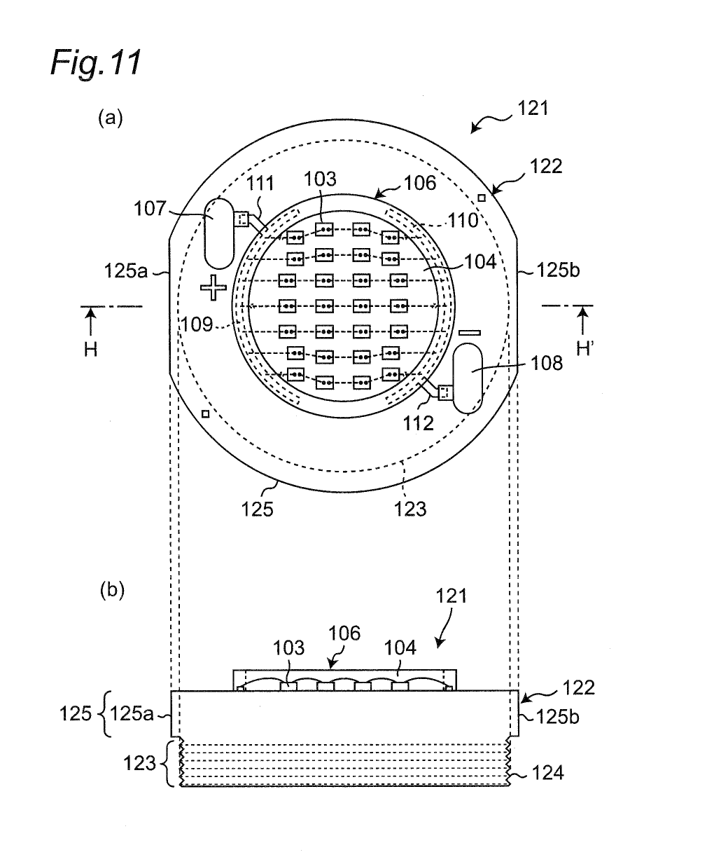

FIG. 11 is a view showing a modification of the light-emitting apparatus according to the sixth embodiment, wherein FIG. 11(a) is a top view and FIG. 11(b) is a sectional view taken along the line H-H′ of FIG. 11(a). In this modification, the same component members as in the light-emitting apparatus 101 shown in FIG. 10 are designated by the same reference signs and description on those component members will be omitted. This modification relates to a light-emitting apparatus having two flat surfaces in the side surfaces of the head portion in the light-emitting apparatus.

A light-emitting apparatus 121 shown in FIG. 11 has a generally circular-shaped Al substrate 122 and a light-emitting part 106 provided thereon, the light-emitting part 106 being identical in structure to that of the light-emitting apparatus 101 shown in FIG. 10. That is, there is provided an insulating layer (not shown) in areas between the Al substrate 122 and such members as the anode wiring pattern 109, the cathode wiring pattern 110, the anode-electrode land portion 107, the cathode-electrode land portion 108, the anode-side conducting part 111 and the cathode-side conducting part 112. Alternatively, an insulating layer may be formed overall on the Al substrate 122 and, the anode wiring pattern 109, the cathode wiring pattern 110, the anode-electrode land portion 107, the cathode-electrode land portion 108, the anode-side conducting part 111, the cathode-side conducting part 112 and the LED chips 103 may be mounted on the insulating layer.

In this light-emitting apparatus 121, on a back surface (other main surface) side of the Al substrate 122 opposite to its top surface (one main surface) that is the surface for formation of the light-emitting part 106, a smaller-diameter portion 123 having a diameter smaller than the top surface side diameter is formed as shown in FIG. 11(b). A male thread 124 is formed on the side surface of the smaller-diameter portion 123 to form the heat-sink attachment part. Also, mutually opposing two flat surfaces 125a, 125b are formed in the side surface of a larger-diameter portion 125 of the generally circular-shaped Al substrate 122. Therefore, during the process of attaching the light-emitting apparatus 121 to the heat sink, using the two flat surfaces 125a, 125b may make it easier to tighten the Al substrate 122, facilitating the fixing of the light-emitting apparatus 121 to the heat sink. In addition, a distance between the two flat surfaces 125a, 125b of the larger-diameter portion 125 is preferably set to a standard size. In this case, it is allowable to use a wrench or spanner for tightening of the Al substrate 122.

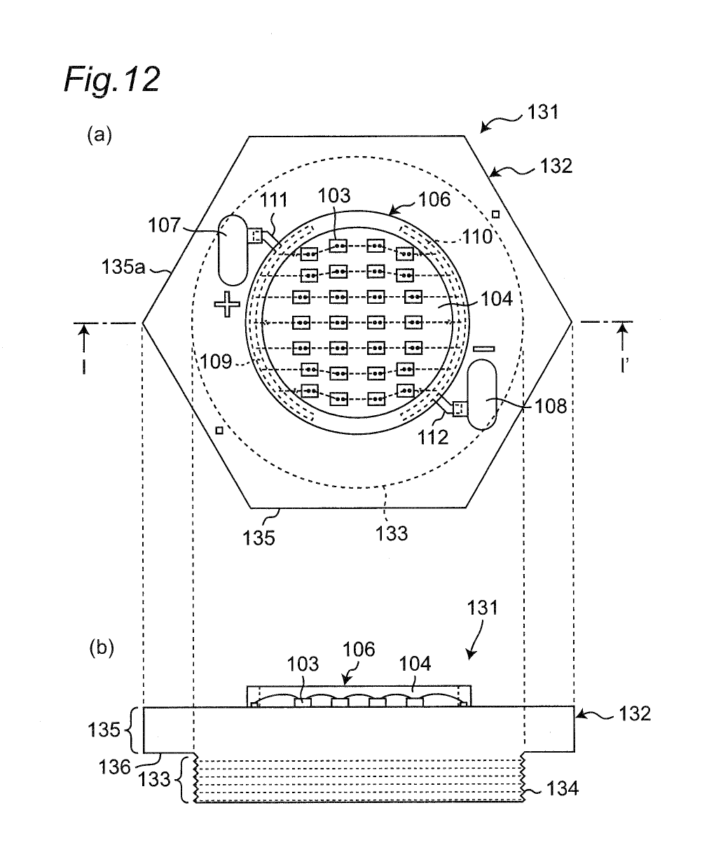

FIG. 12 is a view showing another modification of the light-emitting apparatus according to the sixth embodiment, wherein FIG. 12(a) is a top view and FIG. 12(b) is a sectional view taken along the line I-I′ of FIG. 12(a). In this modification, the same component members as in the light-emitting apparatus 101 shown in FIG. 10 are designated by the same reference signs and description on those component members will be omitted. This modification relates to a light-emitting apparatus having a polygonal head portion as an example having three or more flat surfaces in side surfaces of the head portion of the light-emitting apparatus.

A light-emitting apparatus 131 shown in FIG. 12 has a generally hexagonal-shaped Al (aluminum) substrate 132 and a light-emitting part 106 formed thereon, the light-emitting part 106 being identical in structure to that of the light-emitting apparatus 101 shown in FIG. 10. That is, there is provided an insulating layer (not shown) made from zirconia-based ceramic material between the Al substrate 132 and such members as the anode wiring pattern 109, the cathode wiring pattern 110, the anode-electrode land portion 107, the cathode-electrode land portion 108, the anode-side conducting part 111 and the cathode-side conducting part 112. Alternatively, an insulating layer made from zirconia-based ceramic material may be formed overall on the Al substrate 132 and, the anode wiring pattern 109, the cathode wiring pattern 110, the anode-electrode land portion 107, the cathode-electrode land portion 108, the anode-side conducting part 111, the cathode-side conducting part 112 and the LED chips 103 may be mounted on the insulating layer.

In this light-emitting apparatus 131, as shown in FIG. 12(b), the Al substrate 132 has a circular portion 133 on its back surface (the claimed other main surface) side opposite from its top surface (the claimed one main surface) that is a surface for formation of the light-emitting part 76. The circular portion 133 is a smaller-diameter portion smaller in diameter than an inscribed circle of the hexagonal shape as the external shape of the Al substrate 132. A male thread 134 is formed on the side surface, or peripheral surface, of the circular portion 133 to form the heat-sink attachment part.

Also, a head portion 135 that is a larger-diameter portion of the Al substrate 132 is formed into a generally hexagonal shape, having six flat surfaces 135a. That is, the individual flat surfaces 135a form individual edges of the hexagonal shape. Therefore, during the process of attaching the light-emitting apparatus 131 to the heat sink, using the flat surfaces 135a may make it easier to tighten the Al substrate 132, facilitating the fixing of the light-emitting apparatus 131 to the heat sink. Thus, a step portion 136 between the head portion 135 and the circular portion 133 in the Al substrate 132 may be set into close contact with the surface of the heat sink. In addition, the hexagonal shape of the head portion 135 is preferably set to a standard size. Setting the size of the hexagonal shape of the head portion 135 to a standard size may make it allowable to use a wrench or spanner for tightening of the Al substrate 132.

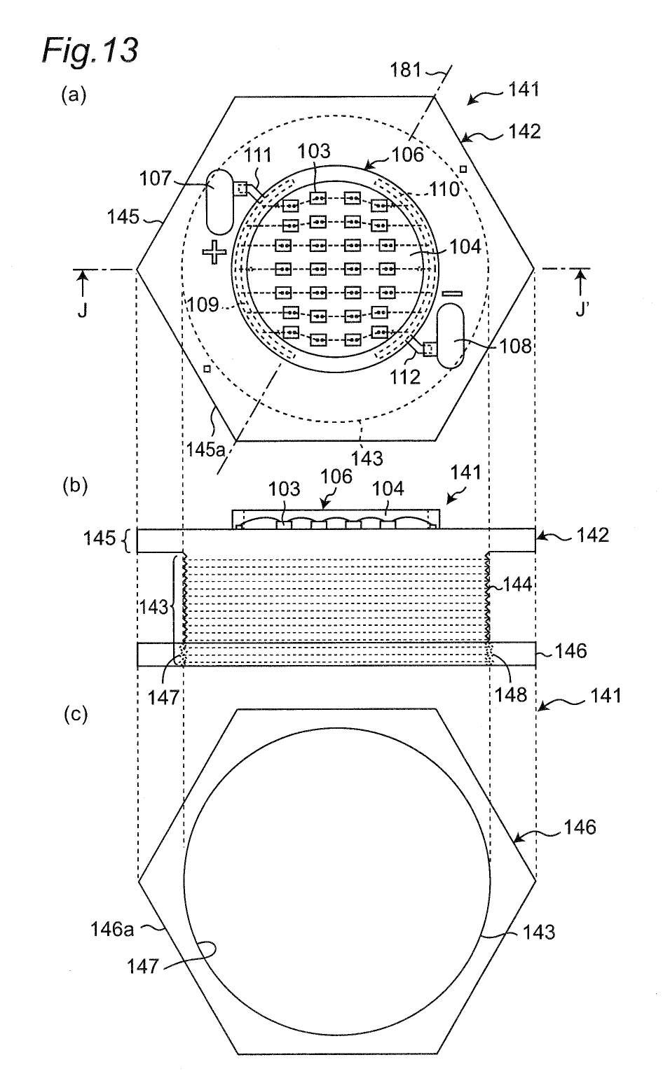

FIG. 13 is a view showing another modification of the light-emitting apparatus according to the sixth embodiment, wherein FIG. 13(a) is a top view, FIG. 13(b) is a sectional view taken along the line J-J′ of FIG. 13(a), and FIG. 13(c) is a bottom view. In this modification, the same component members as in the light-emitting apparatus 101 shown in FIG. 10 are designated by the same reference signs and description on those component members will be omitted. This modification relates to a light-emitting apparatus which enables the tightening of the head portion of the light-emitting apparatus to the heat sink to be strengthened.

A light-emitting apparatus 141 shown in FIG. 13 has a generally hexagonal-shaped Al (aluminum) substrate 142 and a light-emitting part 106 provided thereon, the light-emitting part 106 being identical in structure to that of the light-emitting apparatus 101 shown in FIG. 10. Therefore, the cathode-electrode land portion 108, the anode-side conducting part 111 and the cathode-side conducting part 112, there is provided an insulating layer (not shown) made from zirconia-based ceramic material in areas between the Al substrate 142 and such members as the anode wiring pattern 109, the cathode wiring pattern 110, the anode-electrode land portion 107. Alternatively, an insulating layer made from zirconia-based ceramic material may be formed overall on the Al substrate 142 and, the anode wiring pattern 109, the cathode wiring pattern 110, the anode-electrode land portion 107, the cathode-electrode land portion 108, the anode-side conducting part 111, the cathode-side conducting part 112 and the LED chips 103 may be mounted on the insulating layer.

In this modification, as shown in FIG. 13(b), the Al substrate 142 has a circular portion 143 on its back surface (the claimed other main surface) side opposite from its top surface (the claimed one main surface) that is a surface for formation of the light-emitting part 106. The circular portion 143 is a smaller-diameter portion smaller in diameter than an inscribed circle of the hexagonal shape as the external shape of the Al substrate 142. Also, a male thread 144 is formed on the side surface, or peripheral surface, of the circular portion 143 to form the heat-sink attachment part. Furthermore, there is provided a clamping member 146 formed of a generally hexagonal-shaped plate member, which is generally similar in shape to a generally hexagonal-shaped head portion 145 as a larger-diameter portion of the Al substrate 142. A through hole 147 into which the circular portion 143 of the Al substrate 142 is to be inserted is bored in the clamping member 146. A female thread 148 to be engaged with the male thread 144 of the circular portion 143 is formed on the side surface of the through hole 147.

With regard to the light-emitting apparatus 141 having the above-described structure, the circular portion 143 of the generally hexagonal-shaped Al substrate 142 is inserted through the light-emitting apparatus attachment through hole of the heat sink (not shown). Then, the female thread 148 of the clamping member 146 is engaged with the male thread 144 formed in the circular portion 143 of the Al substrate 142 protruding from the through hole of the heat sink. Thus, by tightening the clamping member 146 against the Al substrate 142, the generally hexagonal-shaped head portion 145 of the Al substrate 142 is set into close contact with the surface of the heat sink.

In this case, the head portion 145 and the clamping member 146 of the Al substrate 142 in the light-emitting apparatus 141 are formed into a generally hexagonal shape, each having six flat surfaces 145a, 146a. Therefore, during the process of attaching the light-emitting apparatus 141 to the heat sink, using these flat surfaces 145a, 146a may make it easier to tighten the Al substrate 142, facilitating the fixing of the light-emitting apparatus 141 to the heat sink. In addition, the size of the hexagonal shape of the head portion 145 and the clamping member 146 is preferably set to a standard size. Setting the size of the hexagonal shape of the head portion 145 and the clamping member 146 to a standard size may make it allowable to use a wrench or spanner for tightening of the Al substrate 142 and the clamping member 146.

This modification has been described on a case where the clamping member 146 is applied to the light-emitting apparatus 131 having the generally hexagonal-shaped head portion 135 shown in FIG. 12. However, the invention is not limited to this, and the clamping member may be applied also to light-emitting apparatuses of other types such as a light-emitting apparatus having one flat surface in the head portion of the substrate as shown in FIG. 10, a light-emitting apparatus having a plurality of flat surfaces shown in FIG. 11, a light-emitting apparatus having a polygonal shape other than a hexagonal shape, or the like. Moreover, the shape of the clamping member as well is not limited to a generally hexagonal shape and may be changed as required in accordance with the head portion configuration of the substrate.

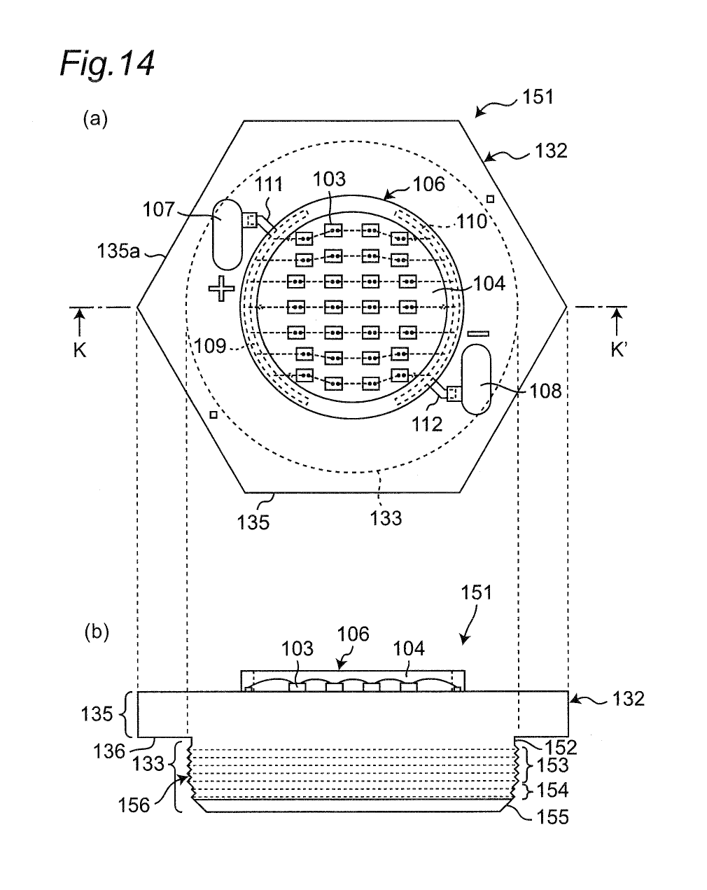

FIG. 14 is a view showing another modification of the light-emitting apparatus according to the sixth embodiment, wherein FIG. 14(a) is a top view and FIG. 14(b) is a sectional view taken along the line K-K′ of FIG. 14(a). This modification relates to another mode of the circular portion 133 of the Al substrate 132 in the light-emitting apparatus 131 having the generally hexagonal-shaped head portion 135 shown in FIG. 12.

In this modification, the same component members as in the light-emitting apparatus 131 shown in FIG. 12 are designated by the same reference signs and description on those component members will be omitted. The circular portion 133, which is a characteristic feature of this modification, will be described below.

In the light-emitting apparatus 131 shown in FIG. 12, the male thread 134 is formed on the side surface of the circular portion 133 of the Al substrate 132 to fulfill a stable, high-repeatability (for ensuring of heat releasability) fixation to a heat sink of a light source mounting unit or the like. In this case, on condition that the male thread 134 is formed on the circular portion 133 having a wholly uniform diameter, as it is, as shown in FIG. 12, there may arise a thread bite (crush of the screw head). This modification is intended to provide against such thread bites.

In a light-emitting apparatus 151 of this modification, as shown in FIG. 14(b), the circular portion 133 of the Al substrate 132 has an undercut 152 adjoining the step portion 136, a chamfered portion 155 located at an end portion on the back surface side of the Al substrate, and a smaller-diameter portion 154 slightly smaller in diameter than a most part of the circular portion 133 and adjoining the chamfered portion 155. Both a base portion 153 defined between the undercut 152 and the smaller-diameter portion 154 and the smaller-diameter portion 154 are provided with a male thread 156 to form the heat-sink attachment part.

In this case, the undercut 152 is set smaller in diameter than the top of the thread ridge of the male thread 156 formed in the base portion 153. Further, the top of the thread ridge of the male thread 156 formed in the smaller-diameter portion 154 is set smaller in diameter than the top of the thread ridge of the male thread 156 formed in the base portion 153. It is noted that the male thread 156 formed in the base portion 153 and the male thread 156 formed in the smaller-diameter portion 154 are identical ones formed in continuation.

As described above, in this modification, the undercut 152, the smaller-diameter portion 154 and the chamfered portion 155 are formed in the circular portion 133 of the Al substrate 132, and the male thread 156 is formed in the base portion 153 equal in diameter to the circular portion 133 as well as in the smaller-diameter portion 154. Therefore, during the process of engaging the male thread 156 with the light-emitting apparatus attachment female thread of the heat sink (not shown), if the center axis of the male thread 156 is inclined relative to the center axis of the female thread, the presence of the chamfered portion 155 and the smaller-diameter portion 154, which are smaller in diameter than the top of the thread ridge of the base portion 153, may make it possible to adjust the inclination of the center axis of the male thread 156. Thus, the male thread 156 may correctly be engaged with the female thread of the heat sink, so that thread bites of the male thread 156 may be prevented.

Further, even if the male thread 156 has been engaged with the female thread with the center axis of the male thread 156 remaining quite slightly inclined relative to the center axis of the female thread, the undercut 152 formed between the step portion 136 and the base portion 153 acts to correct quite a slight deviation of the center axis of the male thread 156 relative to the center axis of the female thread when the end portion of the female thread has reached the undercut 152. Accordingly, thread bites of the male thread 156 may be prevented and moreover close contactability between the step portion 136 and the surface of the heat sink may be improved.

In this modification, the undercut 152, the smaller-diameter portion 154 and the chamfered portion 155 are formed in the circular portion 133. However, it is not necessarily required to provide all of these portions, and providing at least any one of the undercut 152, the smaller-diameter portion 154 and the chamfered portion 155 may make it possible to prevent the thread bites of the male thread 156.

This modification has been described on an example where the undercut 152, the smaller-diameter portion 154 and the chamfered portion 155 are applied to the light-emitting apparatus 131 shown in FIG. 12. However, without being limited to this, the invention may be applied to the individual light-emitting apparatuses of the fourth to sixth embodiments of the structure including the male thread to be engaged with the female thread of the heat sink.

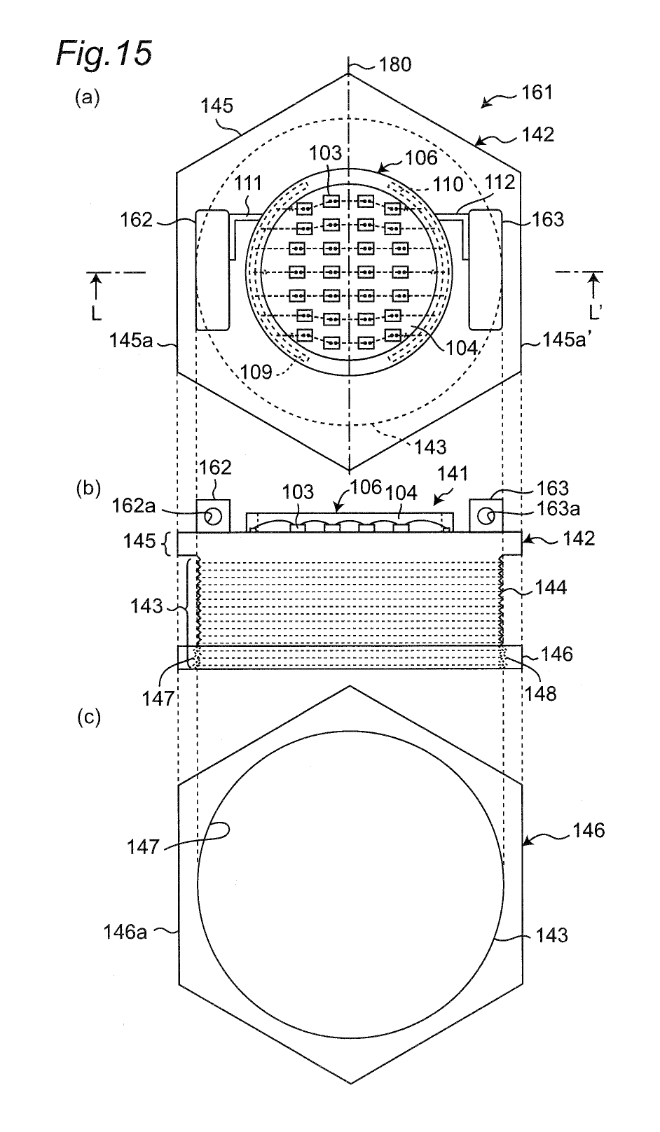

FIG. 15 is a view showing another modification of the light-emitting apparatus according to the sixth embodiment, wherein FIG. 15(a) is a top view, FIG. 15(b) is a sectional view taken along the line L-L′ of FIG. 15(a), and FIG. 15(c) is a bottom view. This modification relates to another mode of the light-emitting apparatus 141 having the clamping member 146 shown in FIG. 13. In this modification, the same component members as in the light-emitting apparatus 141 shown in FIG. 13 are designated by the same reference signs and description on those component members will be omitted.

In FIG. 13, lead wires are connected directly to the land portions. On the other hand, in FIG. 15, connectors (poke-in connectors) are mounted on the land portions for the anode and cathode electrodes, and external lead wires are attached to these connectors to implement connections.

A light-emitting apparatus 161 shown in FIG. 15 has a generally hexagonal-shaped Al substrate 142 and a light-emitting part 106 provided thereon, the light-emitting part 106 being basically similar in structure to that of the light-emitting apparatus 141 shown in FIG. 13. There is provided an insulating layer (not shown) made from zirconia-based ceramic material in areas between the Al substrate 142 and such members as the anode wiring pattern 109, the cathode wiring pattern 110, an anode-electrode connector portion 162 mounted on the anode-electrode land portion, a cathode-electrode connector portion 163 mounted on the cathode-electrode land portion, the anode-side conducting part 111 and the cathode-side conducting part 112. Alternatively, an insulating layer made from zirconia-based ceramic material may be formed on the entire Al substrate 142 and, the anode wiring pattern 109, the cathode wiring pattern 110, the anode-electrode connector portion 162, the cathode-electrode connector portion 163, the anode-side conducting part 111, the cathode-side conducting part 112 and the LED chips 103 may be mounted on the insulating layer.

The anode wiring pattern 109 and the cathode wiring pattern 110 are formed at positions opposed to respective ones of two mutually opposing flat surfaces 145a, 145a′ in the head portion 145 of the hexagonal-shaped Al substrate 142. Further, the anode-electrode connector portion 162 and the cathode-electrode connector portion 163 are also formed at positions opposed to the two mutually opposing flat surfaces 145a, 145a′ so as to extend in parallel with the flat surfaces 145a, 145a′, respectively. That is, the connector portions 162, 163 are formed at positions opposed to each other with a center line 180 of the light-emitting part 106 interposed therebetween. In addition, sockets 162a, 163a for receiving power-feeding lead wires are provided in the anode-electrode connector portion 162 and the cathode-electrode connector portion 163.

The structure on the back surface (other main surface) side of the Al substrate 142 opposite to its top surface (one main surface) that is the surface for formation of the light-emitting part 106 is identical to that of the light-emitting apparatus 141 shown in FIG. 13.

With regard to the light-emitting apparatus 161 of this modification, as in the case of the light-emitting apparatus 141 shown in FIG. 13, the circular portion 143 of the generally hexagonal-shaped Al substrate 142 is inserted through the light-emitting apparatus attachment through hole of the heat sink (not shown). Then, the female thread 148 of the clamping member 146 is engaged with the male thread 144 formed in the circular portion 143 of the Al substrate 142 protruding from the through hole of the heat sink. Thus, by tightening the clamping member 146 against the Al substrate 142, the generally hexagonal-shaped head portion 145 of the Al substrate 142 is set into close contact with the surface of the heat sink.

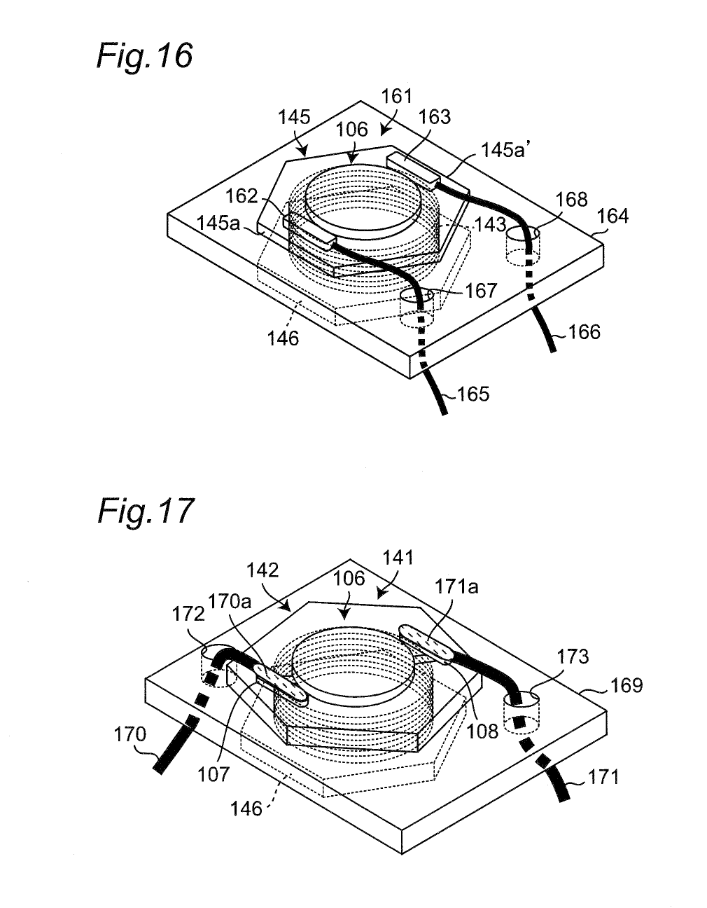

In this case, the anode-electrode connector portion 162 and the cathode-electrode connector portion 163 are formed at positions opposed to each other with the center line 180 of the light-emitting part 106 interposed therebetween in the head portion 145 of the generally hexagonal-shaped Al substrate 142 so as to extend along the flat surfaces 145a, 145a′. Therefore, referring to FIG. 16, during the process of attaching the light-emitting apparatus 161 to a heat sink 164 having through holes 167, 168 for lead wires 165, 166 serving for power feed to the anode-electrode connector portion 162 and the cathode-electrode connector portion 163, positioning of the head portion 145 of the Al substrate 142 is performed such that the array direction of the anode-electrode connector portion 162 and the cathode-electrode connector portion 163 becomes generally parallel to the array direction of the through holes 167, 168, i.e., such that distances between the through holes 167, 168 and the connector portions 162, 163 in the heat sink 164 become generally equal to each other and the shortest. Then, the Al substrate 142 is fixed to the determined position, where the clamping member 146 is tightened.

As a result of this, the distance between the through hole 167 and the anode-electrode connector portion 162 and the distance between the through hole 168 and the cathode-electrode connector portion 163 in the heat sink 164 may be set generally equal to each other and the shortest without unnecessarily elongating the anode-side conducting part 111 and the cathode-side conducting part 112. Furthermore, electrical connections between the anode- and cathode-electrode connector portions 162, 163 and the lead wires 165, 166 may be fulfilled without intercepting the light emission from the light-emitting part 106.

FIG. 17 is a view in which this modification is applied to the light-emitting apparatus 141 shown in FIG. 13. In this case, unsheathed portions 170a, 171a of the lead wires 170, 171 are connected directly to the land portions 107, 108, respectively. In this case also, the anode-electrode land portion 107 and the cathode-electrode land portion 108 are formed at mutually opposing positions with the center line 181 of the light-emitting part 106 interposed therebetween as shown in FIG. 13.

Although the Al substrate 142 in which the head portion 145 is formed into a generally hexagonal shape is used in this modification, yet the head portion 145 is not necessarily required to be hexagonal-shaped. This modification may be applied even to cases in which mutually opposing two flat surfaces 125a, 125b are formed in side surfaces of the head portion, as in the light-emitting apparatus 121 shown in FIG. 11.

Furthermore, the external shapes, or outlines, of the substrates described in the first to sixth embodiments (including modifications) are not limited to the above-described ones, and any closed-figure shapes may be adopted therefor. The closed-figure shapes may be those whose perimeter is made up of straight lines alone or curved lines alone or those whose periphery includes at least one straight-line portion and at least one curved-line portion. Still more, the closed-figure shapes are not limited to convex-figure shapes and may be concave-figure shapes. For example, the closed-figure shapes may be such convex polygonal shapes made up of straight lines as triangles, quadrangles, pentagons and octagons, and also may be arbitrary concave polygonal shapes. Further, the closed-figure shapes may be such closed-figure ones made up of curved lines alone as circular shapes or elliptical shapes, and may be such closed-figure ones as convex curved-line shapes or concave curved-line shapes. Furthermore, the closed-figure shapes may be those including at least one straight-line portion and at least one curved-line portion such as racetrack shapes.

### REFERENCE SIGNS LIST

1, 21, 31, 51, 71, 85, 87, 91, 101, 121, 131, 141, 151, 161 light-emitting apparatus
2, 22, 32, 52, 72, 92 ceramic substrate
3, 33, 53, 53a, 53b, 73, 103 LED chips
4, 34, 54, 74, 104 fluophor-containing resin
6, 23, 36, 56, 76, 93, 106 light-emitting part
7, 37 57a 57b resin dam
8, 38, 58, 109 anode-side wiring pattern
9, 39, 59, 110 cathode-side wiring pattern
10, 40, 62, 77, 107 anode-electrode land portion
11, 41, 63, 78, 108 cathode-electrode land portion
12, 42, 64, 111 anode-side conducting part
13, 43, 65, 112 cathode-side conducting part
14, 15, 17, 18, 27, 28, 47, 48, 66, 67, 69 through hole
16, 26, 46, 68, 81, 95, 164, 169 heat sink
19, 20, 29, 30, 49, 50, 70 screw
19a, 20a, 29a, 30a, 49a, 50a, 70a head of screw
19b, 20b, 70b end portion of screw
24, 25, 44, 45 hole
60, 61 wiring pattern
79, 113, 123, 154 smaller-diameter portion
80, 86, 89, 94, 114, 124, 134, 144, 156 male thread
81a, 95a surface of heat sink
82, 96 hole
83, 97, 148 female thread
84, 136 step portion
88, 115, 125 larger-diameter portion
92a side surface of ceramic substrate
92b bottom surface of ceramic substrate
92c top surface of ceramic substrate
96a bottom surface of hole
102 Cu substrate
115a, 125a, 125b, 135a, 145a, 146a flat surface
122, 132, 142 Al substrate
133, 143 circular portion
135, 145 head portion of Al substrate
146 clamping member
147 through hole
152 undercut
153 base portion
155 chamfered portion
162 anode-electrode connector portion
163 cathode-electrode connector portion
165, 166, 170, 171 lead wire
167, 168, 172, 173 through hole of heat sink

1-22. (canceled)

23. A light-emitting apparatus comprising:
a substrate having two main surfaces and a side surface;
an anode-electrode land portion or anode-electrode connector portion provided on one of the main surfaces of the substrate for electrically connecting to an external lead wire;
a cathode-electrode land portion or cathode-electrode connector portion provided on the one main surface of the substrate for electrically connecting to an external lead wire;
an anode-side wiring pattern provided on the one main surface of the substrate, to which wiring pattern the anode-electrode land portion or anode-electrode connector portion is connected;
a cathode-side wiring pattern provided on the one main surface of the substrate, to which wiring pattern the cathode-electrode land portion or cathode-electrode connector portion is connected;
a light-emitting part having a plurality of LED chips mounted on the one main surface of the substrate, and a resin sealing the plurality of LED chips, the plurality of LED chips being connected to the anode-side wiring pattern and the cathode-side wiring pattern;
a resin dam arranged and configured to dam up the resin; and
a heat-sink attachment part having a heat-sink attachment male thread formed on the side surface of the substrate.

24. The light-emitting apparatus as claimed in claim 23, wherein the heat-sink attachment part is formed on a side surface that is located on the other main surface side of the substrate.

25. The light-emitting apparatus as claimed in claim 24, wherein the heat-sink attachment part is formed on a side surface of a smaller-diameter portion of the substrate, the smaller-diameter portion being located on the other main surface side of the substrate.

26. The light-emitting apparatus as claimed in claim 25, wherein at least one flat surface is formed in a side surface of a larger-diameter portion of the substrate, the larger-diameter portion being located on the one main surface side of the substrate.

27. The light-emitting apparatus as claimed in claim 26, wherein two flat surfaces are formed at mutually opposing positions in the side surface of the larger-diameter portion of the substrate.

28. The light-emitting apparatus as claimed in claim 26, wherein a cross section of the larger-diameter portion in the substrate has a shape of polygon, and the flat surfaces form individual edges of the polygon.

29. The light-emitting apparatus as claimed in claim 26, comprising:
a clamping member for holding the heat sink against the larger-diameter portion, the clamping member including a female thread to be engaged with the male thread of the heat-sink attachment part.

30. The light-emitting apparatus as claimed in claim 23, wherein the anode-electrode land portion or connecter portion and the cathode-electrode land portion or connecter portion are provided at mutually opposing positions with a center line of the light-emitting part interposed therebetween.

31. The light-emitting apparatus as claimed in claim 24, wherein the heat-sink attachment part is formed on a side surface of a larger-diameter portion of the substrate, the larger-diameter portion being located on the other main surface side of the substrate.

32. The light-emitting apparatus as claimed in claim 23, wherein the heat-sink attachment part is formed on the entire side surface of the substrate.

33. The light-emitting apparatus as claimed in claim 23, wherein the heat-sink attachment part includes:
a base portion;
an undercut formed on the substrate's one main surface side of the base portion;
a chamfered portion formed on the substrate's other main surface side of the base portion; and
a smaller-diameter portion located between the base portion and the chamfered portion, the smaller-diameter portion being smaller in diameter than the base portion,
the base portion and the smaller-diameter portion having the heat-sink attachment male thread,
a top of a thread ridge of the male thread formed in the smaller-diameter portion being smaller in diameter than a top of a thread ridge of the male thread formed in the base portion.

34. The light-emitting apparatus as claimed in claim 23, wherein the heat-sink attachment male thread has a larger external shape as viewed in a plan view of the light-emitting apparatus than that of the resin dam.

35. The light-emitting apparatus as claimed in claim 23, wherein the one main surface of the substrate has, between the resin dam and an edge of the substrate, an area that is not sealed with the resin, and the anode-electrode land portion or connector portion and the cathode-electrode land portion or connector portion are arranged in the area not sealed with the resin.
